(19) United States
(12) Patent Application Publication
(10) Pub. No.: US 2026/0030953 A1
(43) Pub. Date: Jan. 29, 2026

(54) DOOR LATCH SYSTEM

(71) Applicant: Aristocrat Technologies Australia Pty Limited, North Ryde (AU)

(72) Inventors: Noel Voloh, Bondi Junction (AU); Vishnuraj Puthanpurayil, Epping (AU); Calvin Kim, Baulkham Hills (AU)

(21) Appl. No.: 18/807,344

(22) Filed: Aug. 16, 2024

Related U.S. Application Data
(60) Provisional application No. 63/676,189, filed on Jul. 26, 2024.

(51) Int. Cl. G07F 17/32; H05K 5/02

(52) U.S. Cl. CPC G07F 17/3216; H05K 5/0221

(57) ABSTRACT

Various features of a door latch system are provided which may be used with electronic gaming machines (EGMs). Some door latch systems have a door latch having, a housing, a cam inside the housing, rotatably connected to the housing, and configured to be in a closed position and an open position, and a trigger inside the housing, rotatably connected to the housing, and configured to be in a first trigger position and a second trigger position, an actuator configured to slide along an axis between a first actuator position and a second actuator position, a cable connected to the trigger and the actuator, and an elastic member contacting the actuator. The actuator is configured to push the cable when moving from the second actuator position to the first actuator position and thereby cause the cable to move the trigger from the second trigger position to the first trigger position.

### RELATED APPLICATION

The present application claims priority to U.S. Provisional Patent Application No. 63/676,189, filed Jul. 26, 2024, and entitled “DOOR LATCH SYSTEM” (Attorney Docket No. ARISP084PUS) which is hereby incorporated by reference in its entirety.

### BACKGROUND

Electronic gaming machines (“EGMs”) or gaming devices provide a variety of wagering games such as slot games, video poker games, video blackjack games, roulette games, video bingo games, keno games and other types of games that are frequently offered at casinos and other locations. Play on EGMs typically involves a player establishing a credit balance by inputting money, or another form of monetary credit, and placing a monetary wager (from the credit balance) on one or more outcomes of an instance (or single play) of a primary or base game. In some cases, a player may qualify for a special mode of the base game, a secondary game, or a bonus round of the base game by attaining a certain winning combination or triggering event in, or related to, the base game, or after the player is randomly awarded the special mode, secondary game, or bonus round. In the special mode, secondary game, or bonus round, the player is given an opportunity to win extra game credits, game tokens or other forms of payout. In the case of “game credits” that are awarded during play, the game credits are typically added to a credit meter total on the EGM and can be provided to the player upon completion of a gaming session or when the player wants to “cash out.”

“Slot” type games are often displayed to the player in the form of various symbols arrayed in a row-by-column grid or matrix. Specific matching combinations of symbols along predetermined paths (or paylines) through the matrix indicate the outcome of the game. The display typically highlights winning combinations/outcomes for identification by the player. Matching combinations and their corresponding awards are usually shown in a “pay-table” which is available to the player for reference. Often, the player may vary his/her wager to include differing numbers of paylines and/or the amount bet on each line. By varying the wager, the player may sometimes alter the frequency or number of winning combinations, frequency or number of secondary games, and/or the amount awarded.

Typical games use a random number generator (RNG) to randomly determine the outcome of each game. The game is designed to return a certain percentage of the amount wagered back to the player over the course of many plays or instances of the game, which is generally referred to as return to player (RTP). The RTP and randomness of the RNG ensure the fairness of the games and are highly regulated. Upon initiation of play, the RNG randomly determines a game outcome and symbols are then selected which correspond to that outcome. Notably, some games may include an element of skill on the part of the player and are therefore not entirely random.

Electronic gaming machines are complex devices with display devices and are often housed within cabinets having multiple access points in the form of doors or trays that may be opened or slid out in order to access internal components, cables, connectors, etc.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

In some embodiments, a door latch system may be provided. The door latch system may have a door latch having a housing, a cam having a flag, the cam positioned inside the housing and rotatably connected to the housing, and configured to be in a closed position and an open position, and a trigger positioned inside the housing, the trigger rotatably connected to the housing, and configured to be in a first trigger position and a second trigger position, an actuator separate from the housing and configured to slide along an axis between a first actuator position and a second actuator position, a cable having a first end connected to the trigger and a second end connected to the actuator, and an elastic member contacting the actuator. In the first trigger position, the trigger may be configured to retain the cam in the closed position. The trigger may be configured to release the cam from the closed position when moving from the first trigger position to the second trigger position. In the second trigger position, the trigger may not retain the cam in the closed position, and the actuator may be configured to pull the cable when moving from the first actuator position to the second actuator position and thereby cause the cable to move the trigger from the first trigger position to the second trigger position. The elastic member may be configured to exert a force on the actuator and move the actuator from the second actuator position to the first actuator position, and the actuator may be configured to push the cable when moving from the second actuator position to the first actuator position and thereby cause the cable to move the trigger from the second trigger position to the first trigger position.

In some embodiments, the actuator may have a body and a first flange extending away from the body, and the elastic member may be in contact with the first flange, and configured to move the first flange and thereby move the actuator from the second actuator position to the first actuator position.

In some such embodiments, the actuator may further have a second flange extending away from the body, and the second flange may be configured to be contacted and moved by a lock mechanism and thereby move the actuator from the first actuator position to the second actuator position.

In some such embodiments, the door latch system may further have the lock mechanism.

In some embodiments, the actuator may have a body having one or more slots, and one or more cylinders that each extend through a respective slot.

In some embodiments, the door latch system may further have an optical sensor configured to detect the presence of the flag.

In some such embodiments, in the closed position, the flag may be in a first flag position, in the open position, the flag may be in a second flag position, and the optical sensor may be configured to generate one or more signals based on whether the flag is in the first flag position or the second flag position.

In some embodiments, the elastic member may be a compression spring configured to be compressed in the second actuator position.

In some embodiments, the elastic member may be a tension spring configured to be extended in the second actuator position.

In some embodiments, the door latch system may further have a cover over at least a portion of the actuator.

In some embodiments, the door latch system may further have a sheath around a length of the cable.

In some embodiments, an electronic gaming machine may be provided. The electronic gaming machine may have a cabinet defining an internal compartment and an opening that provides access to the internal compartment, and having a latch interface, a door rotatably connected to the cabinet and configured to rotate between a closed door position in which the door covers the opening and one or more open door positions in which the door is away from the opening, and a door latch system having a door latch positioned in a first location on a first side of the door and having a housing, a cam having a flag, positioned inside the housing, rotatably connected to the housing, and configured to be in a closed position and an open position, and a trigger positioned inside the housing, rotatably connected to the housing, and configured to be in a first trigger position and a second trigger position, an actuator positioned in a second location on the first side of the door and slidably connected to the door such that the actuator is configured to slide along an axis between a first actuator position and a second actuator position, a cable having a first end connected to the trigger and a second end connected to the actuator, and an elastic member contacting the actuator and the door. The door latch may be configured to engage with the latch interface. In the first trigger position, the trigger may be configured to retain the cam in the closed position, and in the second trigger position, the trigger may not retain the cam in the closed position. The actuator may be configured to pull the cable when moving from the first actuator position to the second actuator position and thereby cause the cable to move the trigger from the first trigger position to the second trigger position. The elastic member may be configured to exert a force on the actuator and move the actuator from the second actuator position to the first actuator position, and the actuator may be configured to push the cable when moving from the second actuator position to the first actuator position and thereby cause the cable to move the trigger from the second trigger position to the first trigger position.

In some embodiments, the actuator may have a body and a first flange extending away from the body, the door may have a stationary component adjacent to the first flange, and the elastic member may be in contact with and span between the first flange and the stationary component, and may be configured to move the first flange and thereby move the actuator from the second actuator position to the first actuator position.

In some embodiments, the electronic gaming machine may further have a rotating lock mechanism configured to receive a key on a second side of the door, contact the actuator, and be rotated in a first direction about a rotation axis and thereby move the actuator from the first actuator position to the second actuator position.

In some such embodiments, the actuator may be further configured to contact and rotate the rotating lock mechanism in a second direction opposite the first direction when moved by the elastic member from the second actuator position to the first actuator position.

In some embodiments, the actuator may have a body having one or more slots, the door latch system may further have one or more connectors, and each connector may extend through a respective slot and is connected to the door.

In some embodiments, the door latch system may further have a sheath around a length of the cable and attached to the door, and the cable may have at least one bend and/or one straight section.

In some embodiments, the electronic gaming machine may further have an optical sensor configured to detect the presence of the flag.

In some such embodiments, the electronic gaming machine may further have a controller configured to receive one or more signals generated by the optical sensor. In the closed position, the flag may be in a first flag position, in the open position, the flag may be in a second flag position, and the optical sensor may be configured to generate the one or more signals based on whether the flag is in the first flag position or the second flag position.

In some embodiments, movement of the actuator from the first actuator position to the second actuator position may be configured to allow the door to be opened by causing the cable to move the trigger to the second trigger position to thereby not retain the cam such that the cam is configured to disengage from the latch interface, the cam may be configured to engage with the latch interface and be rotated about a rotation axis of the cam when the door is moved to the closed position, and movement of the actuator from the second actuator position to the first actuator position may be configured to allow the door to be retained in the closed position by causing the cable to move the trigger to the first trigger position such that the trigger is configured to retain the cam when the cam is engaged and rotated by the latch interface.

Additional aspects will be set forth in the detailed description which follows, and, in part, will be apparent from the disclosure, or may be learned by practice of the disclosed embodiments and/or the claimed subject matter.

The foregoing general description and the following detailed description are illustrative and explanatory and are intended to provide further explanation of the claimed subject matter.

### BRIEF DESCRIPTION OF THE DRAWINGS

FIG. 1 is an exemplary diagram showing several EGMs networked with various gaming-related servers.

FIG. 2A is a block diagram showing various functional elements of an exemplary EGM.

FIG. 2B depicts a casino gaming environment according to one example.

FIG. 2C is a diagram that shows examples of components of a system for providing online gaming according to some aspects of the present disclosure.

FIG. 3 illustrates, in block diagram form, an implementation of a game processing architecture algorithm that implements a game processing pipeline for the play of a game in accordance with various implementations described herein.

FIG. 4 depicts a side view of a door latch system according to disclosed embodiments.

FIG. 5 depicts the side view of the door latch system of FIG. 4 in another configuration according to disclosed embodiments.

FIG. 6 depicts a back view of the door latch system of FIG. 4.

FIG. 7 depicts a back view of the door latch system of FIG. 5.

FIG. 8 depicts the back view of the door latch system in another configuration according to disclosed embodiments.

FIG. 9 depicts the back view of the door latch system of FIG. 6 with a lock mechanism.

FIG. 10 depicts the door latch system of FIG. 9 in another configuration.

FIG. 11A depicts an off-angle view of a portion of the door latch system of FIG. 4.

FIG. 11B depicts an exploded view of the portion of the door latch system of FIG. 11A.

FIG. 12 depicts an off-angle view of the door latch system of FIG. 4 along with a portion of a door.

FIG. 13 depicts an isometric view of an electronic gaming machine according to disclosed embodiments.

FIG. 14 depicts the electronic gaming machine of FIG. 13 with the door in a closed position according to various embodiments.

FIG. 15 depicts an off-angle view of the actuator and an example lock mechanism.

The Figures are provided for the purpose of providing examples and clarity regarding various aspects of this disclosure and are not intended to be limiting.

### DETAILED DESCRIPTION

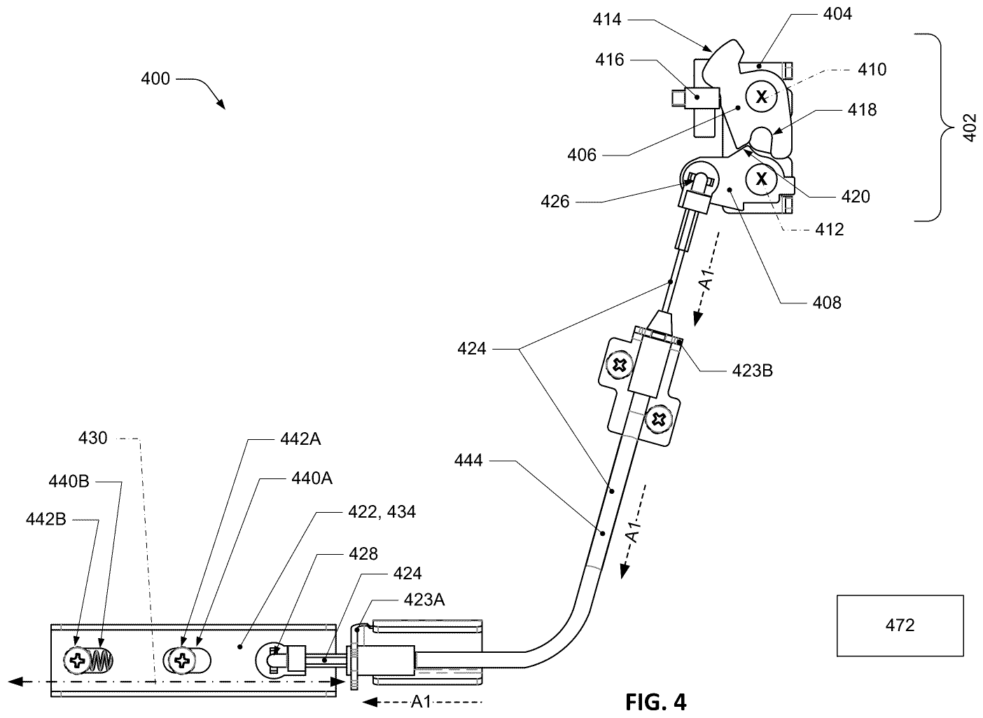

The following discussion provides overall context for electronic gaming machines, some of which may include an enclosure such as those discussed later herein starting with FIG. 4A.

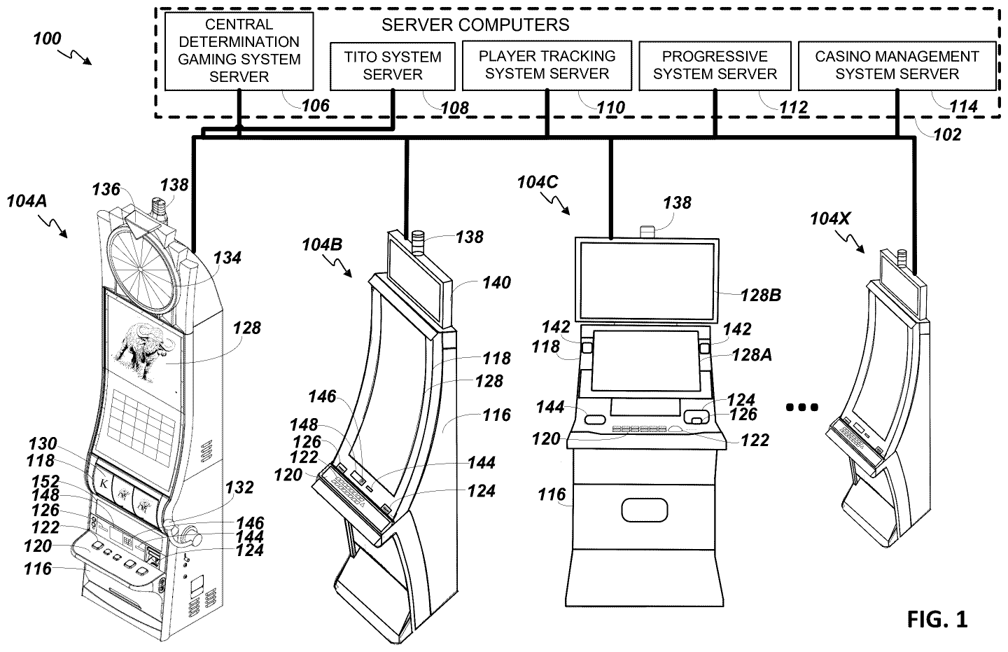

FIG. 1 illustrates several different models of EGMs which may be networked to various gaming-related servers. Shown is a system 100 in a gaming environment including one or more server computers 102 (e.g., slot servers of a casino) that are in communication, via a communications network, with one or more gaming devices 104A-104X (EGMs, slots, video poker, bingo machines, etc.) that can implement one or more aspects of the present disclosure. The gaming devices 104A-104X may alternatively be portable and/or remote gaming devices such as, but not limited to, a smart phone, a tablet, a laptop, or a game console. Gaming devices 104A-104X utilize specialized software and/or hardware to form non-generic, particular machines or apparatuses that comply with regulatory requirements regarding devices used for wagering or games of chance that provide monetary awards.

Communication between the gaming devices 104A-104X and the server computers 102, and among the gaming devices 104A-104X, may be direct or indirect using one or more communication protocols. As an example, gaming devices 104A-104X and the server computers 102 can communicate over one or more communication networks, such as over the Internet through a website maintained by a computer on a remote server or over an online data network including commercial online service providers, Internet service providers, private networks (e.g., local area networks and enterprise networks), and the like (e.g., wide area networks). The communication networks could allow gaming devices 104A-104X to communicate with one another and/or the server computers 102 using a variety of communication-based technologies, such as radio frequency (RF) (e.g., wireless fidelity (WiFi®) and Bluetooth®), cable TV, satellite links and the like.

In some implementations, server computers 102 may not be necessary and/or preferred. For example, in one or more implementations, a stand-alone gaming device such as gaming device 104A, gaming device 104B or any of the other gaming devices 104C-104X can implement one or more aspects of the present disclosure. However, it is typical to find multiple EGMs connected to networks implemented with one or more of the different server computers 102 described herein.

The server computers 102 may include a central determination gaming system server 106, a ticket-in-ticket-out (TITO) system server 108, a player tracking system server 110, a progressive system server 112, and/or a casino management system server 114. Gaming devices 104A-104X may include features to enable operation of any or all servers for use by the player and/or operator (e.g., the casino, resort, gaming establishment, tavern, pub, etc.). For example, game outcomes may be generated on a central determination gaming system server 106 and then transmitted over the network to any of a group of remote terminals or remote gaming devices 104A-104X that utilize the game outcomes and display the results to the players.

Gaming device 104A is often of a cabinet construction which may be aligned in rows or banks of similar devices for placement and operation on a casino floor. The gaming device 104A often includes a main door which provides access to the interior of the cabinet. Gaming device 104A typically includes a button area or button deck 120 accessible by a player that is configured with input switches or buttons 122, an access channel for a bill validator 124, and/or an access channel for a ticket-out printer 126.

In FIG. 1, gaming device 104A is shown as a Relm XL™ model gaming device manufactured by Aristocrat® Technologies, Inc. As shown, gaming device 104A is a reel machine having a gaming display area 118 comprising a number (typically 3 or 5) of mechanical reels 130 with various symbols displayed on them. The mechanical reels 130 are independently spun and stopped to show a set of symbols within the gaming display area 118 which may be used to determine an outcome to the game.

In many configurations, the gaming device 104A may have a main display 128 (e.g., video display monitor) mounted to, or above, the gaming display area 118. The main display 128 can be a high-resolution liquid crystal display (LCD), plasma, light emitting diode (LED), or organic light emitting diode (OLED) panel which may be flat or curved as shown, a cathode ray tube, or other conventional electronically controlled video monitor.

In some implementations, the bill validator 124 may also function as a “ticket-in” reader that allows the player to use a casino issued credit ticket to load credits onto the gaming device 104A (e.g., in a cashless ticket (“TITO”) system). In such cashless implementations, the gaming device 104A may also include a “ticket-out” printer 126 for outputting a credit ticket when a “cash out” button is pressed. Cashless TITO systems are used to generate and track unique bar-codes or other indicators printed on tickets to allow players to avoid the use of bills and coins by loading credits using a ticket reader and cashing out credits using a ticket-out printer 126 on the gaming device 104A. The gaming device 104A can have hardware meters for purposes including ensuring regulatory compliance and monitoring the player credit balance. In addition, there can be additional meters that record the total amount of money wagered on the gaming device, total amount of money deposited, total amount of money withdrawn, total amount of winnings on gaming device 104A.

In some implementations, a player tracking card reader 144, a transceiver for wireless communication with a mobile device (e.g., a player's smartphone), a keypad 146, and/or an illuminated display 148 for reading, receiving, entering, and/or displaying player tracking information is provided in gaming device 104A. In such implementations, a game controller within the gaming device 104A can communicate with the player tracking system server 110 to send and receive player tracking information.

Gaming device 104A may also include a bonus topper wheel 134. When bonus play is triggered (e.g., by a player achieving a particular outcome or set of outcomes in the primary game), bonus topper wheel 134 is operative to spin and stop with indicator arrow 136 indicating the outcome of the bonus game. Bonus topper wheel 134 is typically used to play a bonus game, but it could also be incorporated into play of the base or primary game.

A candle 138 may be mounted on the top of gaming device 104A and may be activated by a player (e.g., using a switch or one of buttons 122) to indicate to operations staff that gaming device 104A has experienced a malfunction or the player requires service. The candle 138 is also often used to indicate a jackpot has been won and to alert staff that a hand payout of an award may be needed.

There may also be one or more information panels 152 which may be a back-lit, silkscreened glass panel with lettering to indicate general game information including, for example, a game denomination (e.g., $0.25 or $1), pay lines, pay tables, and/or various game related graphics. In some implementations, the information panel(s) 152 may be implemented as an additional video display.

Gaming devices 104A have traditionally also included a handle 132 typically mounted to the side of main cabinet 116 which may be used to initiate game play.

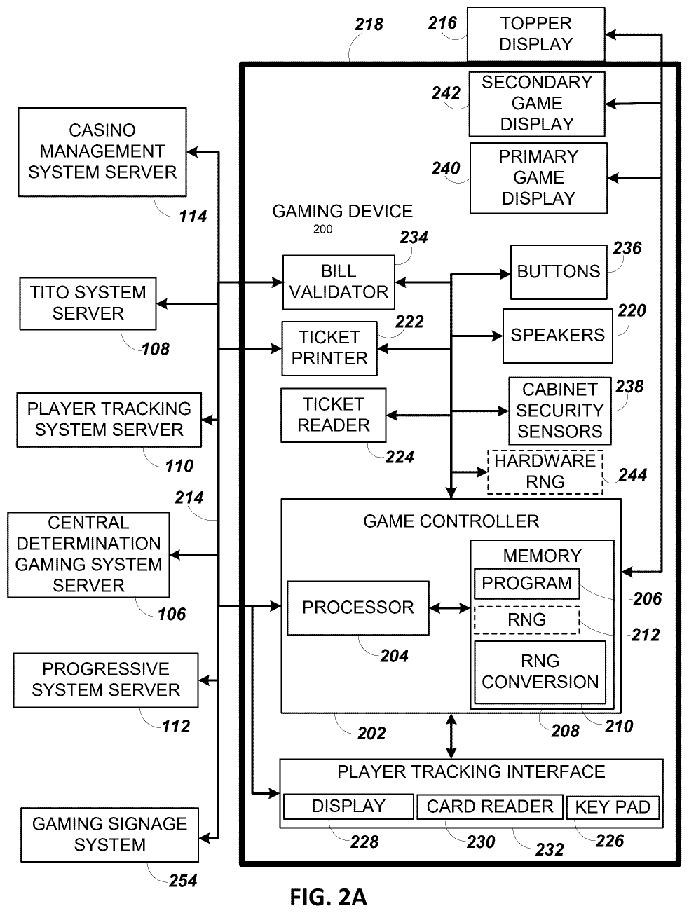

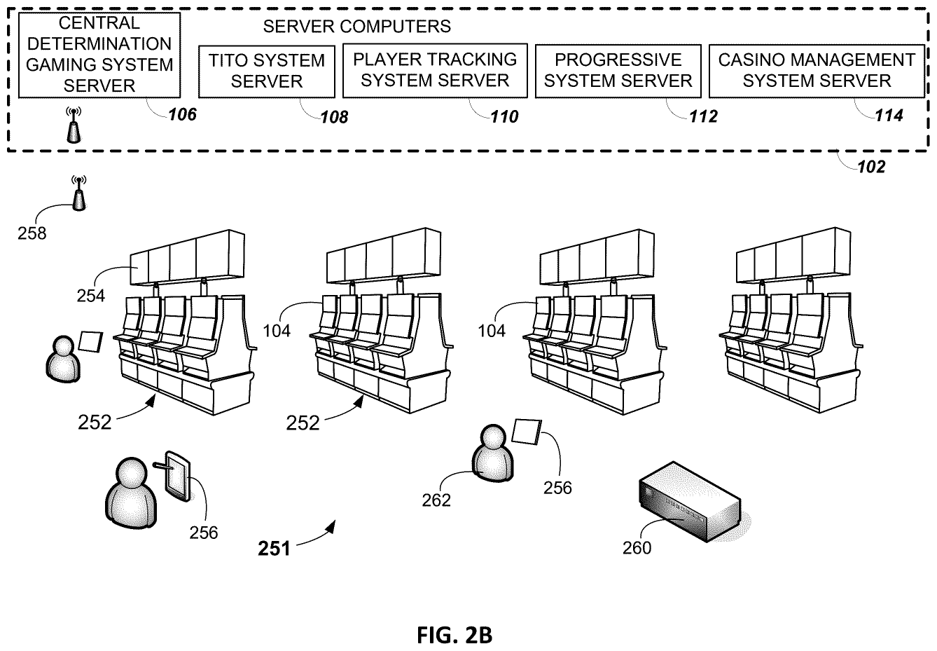

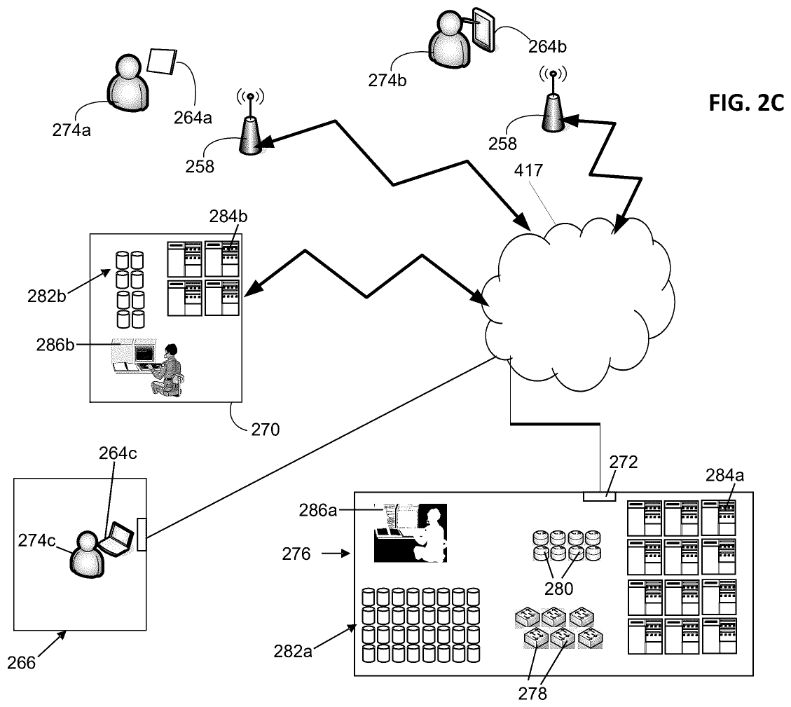

Many or all the above-described components can be controlled by circuitry (e.g., a game controller) housed inside the main cabinet 116 of the gaming device 104A, the details of which are shown in FIG. 2A.

An alternative example gaming device 104B illustrated in FIG. 1 is the Arc™ model gaming device manufactured by Aristocrat® Technologies, Inc. Note that where possible, reference numerals identifying similar features of the gaming device 104A implementation are also identified in the gaming device 104B implementation using the same reference numbers. Gaming device 104B does not include physical reels and instead shows game play functions on main display 128. An optional topper screen 140 may be used as a secondary game display for bonus play, to show game features or attraction activities while a game is not in play, or any other information or media desired by the game designer or operator. In some implementations, the optional topper screen 140 may also or alternatively be used to display progressive jackpot prizes available to a player during play of gaming device 104B.

Example gaming device 104B includes a main cabinet 116 including a main door which opens to provide access to the interior of the gaming device 104B. The main or service door is typically used by service personnel to refill the ticket-out printer 126 and collect bills and tickets inserted into the bill validator 124. The main or service door may also be accessed to reset the machine, verify and/or upgrade the software, and for general maintenance operations.

Another example gaming device 104C shown is the Helix™ model gaming device manufactured by Aristocrat Technologies, Inc. Gaming device 104C includes a main display 128A that is in a landscape orientation. Although not illustrated by the front view provided, the main display 128A may have a curvature radius from top to bottom, or alternatively from side to side. In some implementations, main display 128A is a flat panel display. Main display 128A is typically used for primary game play while secondary display 128B is typically used for bonus game play, to show game features or attraction activities while the game is not in play or any other information or media desired by the game designer or operator. In some implementations, example gaming device 104C may also include speakers 142 to output various audio such as game sound, background music, etc.

Many different types of games, including mechanical slot games, video slot games, video poker, video black jack, video pachinko, keno, bingo, and lottery, may be provided with or implemented within the depicted gaming devices 104A-104C and other similar gaming devices. Each gaming device may also be operable to provide many different games. Games may be differentiated according to themes, sounds, graphics, type of game (e.g., slot game vs. card game vs. game with aspects of skill), denomination, number of paylines, maximum jackpot, progressive or non-progressive, bonus games, and may be deployed for operation in Class 2 or Class 3, etc.

FIG. 2A is a block diagram depicting exemplary internal electronic components of a gaming device 200 connected to various external systems. All or parts of the gaming device 200 shown could be used to implement any one of the example gaming devices 104A-X depicted in FIG. 1. As shown in FIG. 2A, gaming device 200 includes a topper display 216 or another form of a top box (e.g., a topper wheel, a topper screen, etc.) that sits above cabinet 218. Cabinet 218 or topper display 216 may also house a number of other components which may be used to add features to a game being played on gaming device 200, including speakers 220, a ticket printer 222 which prints bar-coded tickets or other media or mechanisms for storing or indicating a player's credit value, a ticket reader 224 which reads bar-coded tickets or other media or mechanisms for storing or indicating a player's credit value, and a player tracking interface 232. Player tracking interface 232 may include a keypad 226 for entering information, a player tracking display 228 for displaying information (e.g., an illuminated or video display), a card reader 230 for receiving data and/or communicating information to and from media or a device such as a smart phone enabling player tracking. FIG. 2 also depicts utilizing a ticket printer 222 to print tickets for a TITO system server 108. Gaming device 200 may further include a bill validator 234, player-input buttons 236 for player input, cabinet security sensors 238 to detect unauthorized opening of the cabinet 218, a primary game display 240, and a secondary game display 242, each coupled to and operable under the control of game controller 202.

The games available for play on the gaming device 200 are controlled by a game controller 202 that includes one or more processors 204. Processor 204 represents a general-purpose processor, a specialized processor intended to perform certain functional tasks, or a combination thereof. As an example, processor 204 can be a central processing unit (CPU) that has one or more multi-core processing units and memory mediums (e.g., cache memory) that function as buffers and/or temporary storage for data. Alternatively, processor 204 can be a specialized processor, such as an application specific integrated circuit (ASIC), graphics processing unit (GPU), field-programmable gate array (FPGA), digital signal processor (DSP), or another type of hardware accelerator. In another example, processor 204 is a system on chip (SoC) that combines and integrates one or more general-purpose processors and/or one or more specialized processors. Although FIG. 2A illustrates that game controller 202 includes a single processor 204, game controller 202 is not limited to this representation and instead can include multiple processors 204 (e.g., two or more processors).

FIG. 2A illustrates that processor 204 is operatively coupled to memory 208. Memory 208 is defined herein as including volatile and nonvolatile memory and other types of non-transitory data storage components. Volatile memory is memory that do not retain data values upon loss of power. Nonvolatile memory is memory that do retain data upon a loss of power. Examples of memory 208 include random access memory (RAM), read-only memory (ROM), hard disk drives, solid-state drives, universal serial bus (USB) flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, examples of RAM include static random access memory (SRAM), dynamic random access memory (DRAM), magnetic random access memory (MRAM), and other such devices. Examples of ROM include a programmable read-only memory (PROM), an erasable programmable read-only memory (EPROM), an electrically erasable programmable read-only memory (EEPROM), or other like memory device. Even though FIG. 2A illustrates that game controller 202 includes a single memory 208, game controller 202 could include multiple memories 208 for storing program instructions and/or data.

Memory 208 can store one or more game programs 206 that provide program instructions and/or data for carrying out various implementations (e.g., game mechanics) described herein. Stated another way, game program 206 represents an executable program stored in any portion or component of memory 208. In one or more implementations, game program 206 is embodied in the form of source code that includes human-readable statements written in a programming language or machine code that contains numerical instructions recognizable by a suitable execution system, such as a processor 204 in a game controller or other system. Examples of executable programs include: (1) a compiled program that can be translated into machine code in a format that can be loaded into a random access portion of memory 208 and run by processor 204; (2) source code that may be expressed in proper format such as object code that is capable of being loaded into a random access portion of memory 208 and executed by processor 204; and (3) source code that may be interpreted by another executable program to generate instructions in a random access portion of memory 208 to be executed by processor 204.

Alternatively, game programs 206 can be set up to generate one or more game instances based on instructions and/or data that gaming device 200 exchanges with one or more remote gaming devices, such as a central determination gaming system server 106 (not shown in FIG. 2A but shown in FIG. 1). For purpose of this disclosure, the term “game instance” refers to a play or a round of a game that gaming device 200 presents (e.g., via a user interface (UI)) to a player. The game instance is communicated to gaming device 200 via the network 214 and then displayed on gaming device 200. For example, gaming device 200 may execute game program 206 as video streaming software that allows the game to be displayed on gaming device 200. When a game is stored on gaming device 200, it may be loaded from memory 208 (e.g., from a read only memory (ROM)) or from the central determination gaming system server 106 to memory 208.

Gaming devices, such as gaming device 200, are highly regulated to ensure fairness and, in many cases, gaming device 200 is operable to award monetary awards (e.g., typically dispensed in the form of a redeemable voucher). Therefore, to satisfy security and regulatory requirements in a gaming environment, hardware and software architectures are implemented in gaming devices 200 that differ significantly from those of general-purpose computers. Adapting general purpose computers to function as gaming devices 200 is not simple or straightforward because of: (1) the regulatory requirements for gaming devices 200, (2) the harsh environment in which gaming devices 200 operate, (3) security requirements, (4) fault tolerance requirements, and (5) the requirement for additional special purpose componentry enabling functionality of an EGM. These differences require substantial engineering effort with respect to game design implementation, game mechanics, hardware components, and software.

One regulatory requirement for games running on gaming device 200 generally involves complying with a certain level of randomness. Typically, gaming jurisdictions mandate that gaming devices 200 satisfy a minimum level of randomness without specifying how a gaming device 200 should achieve this level of randomness. To comply, FIG. 2A illustrates that gaming device 200 could include an RNG 212 that utilizes hardware and/or software to generate RNG outcomes that lack any pattern. The RNG operations are often specialized and non-generic in order to comply with regulatory and gaming requirements. For example, in a slot game, game program 206 can initiate multiple RNG calls to RNG 212 to generate RNG outcomes, where each RNG call and RNG outcome corresponds to an outcome for a reel. In another example, gaming device 200 can be a Class II gaming device where RNG 212 generates RNG outcomes for creating Bingo cards. In one or more implementations, RNG 212 could be one of a set of RNGs operating on gaming device 200. More generally, an output of the RNG 212 can be the basis on which game outcomes are determined by the game controller 202. Game developers could vary the degree of true randomness for each RNG (e.g., pseudorandom) and utilize specific RNGs depending on game requirements. The output of the RNG 212 can include a random number or pseudorandom number (either is generally referred to as a “random number”).

In FIG. 2A, RNG 212 and hardware RNG 244 are shown in dashed lines to illustrate that RNG 212, hardware RNG 244, or both can be included in gaming device 200. In one implementation, instead of including RNG 212, gaming device 200 could include a hardware RNG 244 that generates RNG outcomes. Analogous to RNG 212, hardware RNG 244 performs specialized and non-generic operations in order to comply with regulatory and gaming requirements. For example, because of regulation requirements, hardware RNG 244 could be a random number generator that securely produces random numbers for cryptography use. The gaming device 200 then uses the secure random numbers to generate game outcomes for one or more game features. In another implementation, the gaming device 200 could include both hardware RNG 244 and RNG 212. RNG 212 may utilize the RNG outcomes from hardware RNG 244 as one of many sources of entropy for generating secure random numbers for the game features.

Another regulatory requirement for running games on gaming device 200 includes ensuring a certain level of RTP. Similar to the randomness requirement discussed above, numerous gaming jurisdictions also mandate that gaming device 200 provides a minimum level of RTP (e.g., RTP of at least 75%). A game can use one or more lookup tables (also called weighted tables) as part of a technical solution that satisfies regulatory requirements for randomness and RTP. In particular, a lookup table can integrate game features (e.g., trigger events for special modes or bonus games; newly introduced game elements such as extra reels, new symbols, or new cards; stop positions for dynamic game elements such as spinning reels, spinning wheels, or shifting reels; or card selections from a deck) with random numbers generated by one or more RNGs, so as to achieve a given level of volatility for a target level of RTP. (In general, volatility refers to the frequency or probability of an event such as a special mode, payout, etc. For example, for a target level of RTP, a higher-volatility game may have a lower payout most of the time with an occasional bonus having a very high payout, while a lower-volatility game has a steadier payout with more frequent bonuses of smaller amounts.) Configuring a lookup table can involve engineering decisions with respect to how RNG outcomes are mapped to game outcomes for a given game feature, while still satisfying regulatory requirements for RTP. Configuring a lookup table can also involve engineering decisions about whether different game features are combined in a given entry of the lookup table or split between different entries (for the respective game features), while still satisfying regulatory requirements for RTP and allowing for varying levels of game volatility.

FIG. 2A illustrates that gaming device 200 includes an RNG conversion engine 210 that translates the RNG outcome from RNG 212 to a game outcome presented to a player. To meet a designated RTP, a game developer can set up the RNG conversion engine 210 to utilize one or more lookup tables to translate the RNG outcome to a symbol element, stop position on a reel strip layout, and/or randomly chosen aspect of a game feature. As an example, the lookup tables can regulate a prize payout amount for each RNG outcome and how often the gaming device 200 pays out the prize payout amounts. The RNG conversion engine 210 could utilize one lookup table to map the RNG outcome to a game outcome displayed to a player and a second lookup table as a pay table for determining the prize payout amount for each game outcome. The mapping between the RNG outcome to the game outcome controls the frequency in hitting certain prize payout amounts.

FIG. 2A also depicts that gaming device 200 is connected over network 214 to player tracking system server 110. Player tracking system server 110 may be, for example, an OASIS® system manufactured by Aristocrat® Technologies, Inc. Player tracking system server 110 is used to track play (e.g., amount wagered, games played, time of play and/or other quantitative or qualitative measures) for individual players so that an operator may reward players in a loyalty program. The player may use the player tracking interface 232 to access his/her account information, activate free play, and/or request various information. Player tracking or loyalty programs seek to reward players for their play and help build brand loyalty to the gaming establishment. The rewards typically correspond to the player's level of patronage (e.g., to the player's playing frequency and/or total amount of game plays at a given casino). Player tracking rewards may be complimentary and/or discounted meals, lodging, entertainment and/or additional play. Player tracking information may be combined with other information that is now readily obtainable by a casino management system.

When a player wishes to play the gaming device 200, he/she can insert cash or a ticket voucher through a coin acceptor (not shown) or bill validator 234 to establish a credit balance on the gaming device. The credit balance is used by the player to place wagers on instances of the game and to receive credit awards based on the outcome of winning instances. The credit balance is decreased by the amount of each wager and increased upon a win. The player can add additional credits to the balance at any time. The player may also optionally insert a loyalty club card into the card reader 230. During the game, the player views with one or more UIs, the game outcome on one or more of the primary game display 240 and secondary game display 242. Other game and prize information may also be displayed.

For each game instance, a player may make selections, which may affect play of the game. For example, the player may vary the total amount wagered by selecting the amount bet per line and the number of lines played. In many games, the player is asked to initiate or select options during course of game play (such as spinning a wheel to begin a bonus round or select various items during a feature game). The player may make these selections using the player-input buttons 236, the primary game display 240 which may be a touch screen, or using some other device which enables a player to input information into the gaming device 200.

During certain game events, the gaming device 200 may display visual and auditory effects that can be perceived by the player. These effects add to the excitement of a game, which makes a player more likely to enjoy the playing experience. Auditory effects include various sounds that are projected by the speakers 220. Visual effects include flashing lights, strobing lights or other patterns displayed from lights on the gaming device 200 or from lights behind the information panel 152 (FIG. 1).

When the player is done, he/she cashes out the credit balance (typically by pressing a cash out button to receive a ticket from the ticket printer 222). The ticket may be “cashed-in” for money or inserted into another machine to establish a credit balance for play.

Additionally, or alternatively, gaming devices 104A-104X and 200 can include or be coupled to one or more wireless transmitters, receivers, and/or transceivers (not shown in FIGS. 1 and 2A) that communicate (e.g., Bluetooth® or other near-field communication technology) with one or more mobile devices to perform a variety of wireless operations in a casino environment. Examples of wireless operations in a casino environment include detecting the presence of mobile devices, performing credit, points, comps, or other marketing or hard currency transfers, establishing wagering sessions, and/or providing a personalized casino-based experience using a mobile application. In one implementation, to perform these wireless operations, a wireless transmitter or transceiver initiates a secure wireless connection between a gaming device 104A-104X and 200 and a mobile device. After establishing a secure wireless connection between the gaming device 104A-104X and 200 and the mobile device, the wireless transmitter or transceiver does not send and/or receive application data to and/or from the mobile device. Rather, the mobile device communicates with gaming devices 104A-104X and 200 using another wireless connection (e.g., WiFi® or cellular network). In another implementation, a wireless transceiver establishes a secure connection to directly communicate with the mobile device. The mobile device and gaming device 104A-104X and 200 sends and receives data utilizing the wireless transceiver instead of utilizing an external network. For example, the mobile device would perform digital wallet transactions by directly communicating with the wireless transceiver. In one or more implementations, a wireless transmitter could broadcast data received by one or more mobile devices without establishing a pairing connection with the mobile devices.

Although FIGS. 1 and 2A illustrate specific implementations of a gaming device (e.g., gaming devices 104A-104X and 200), the disclosure is not limited to those implementations shown in FIGS. 1 and 2. For example, not all gaming devices suitable for implementing implementations of the present disclosure necessarily include top wheels, top boxes, information panels, cashless ticket systems, and/or player tracking systems. Further, some suitable gaming devices have only a single game display that includes only a mechanical set of reels and/or a video display, while others are designed for bar counters or tabletops and have displays that face upwards. Gaming devices 104A-104X and 200 may also include other processors that are not separately shown. Using FIG. 2A as an example, gaming device 200 could include display controllers (not shown in FIG. 2A) configured to receive video input signals or instructions to display images on game displays 240 and 242. Alternatively, such display controllers may be integrated into the game controller 202. The use and discussion of FIGS. 1 and 2 are examples to facilitate ease of description and explanation.

FIG. 2B depicts a casino gaming environment according to one example. In this example, the casino 251 includes banks 252 of EGMs 104. In this example, each bank 252 of EGMs 104 includes a corresponding gaming signage system 254 (also shown in FIG. 2A). According to this implementation, the casino 251 also includes mobile gaming devices 256, which are also configured to present wagering games in this example. The mobile gaming devices 256 may, for example, include tablet devices, cellular phones, smart phones and/or other handheld devices. In this example, the mobile gaming devices 256 are configured for communication with one or more other devices in the casino 251, including but not limited to one or more of the server computers 102, via wireless access points 258.

According to some examples, the mobile gaming devices 256 may be configured for stand-alone determination of game outcomes. However, in some alternative implementations the mobile gaming devices 256 may be configured to receive game outcomes from another device, such as the central determination gaming system server 106, one of the EGMs 104, etc.

Some mobile gaming devices 256 may be configured to accept monetary credits from a credit or debit card, via a wireless interface (e.g., via a wireless payment app), via tickets, via a patron casino account, etc. However, some mobile gaming devices 256 may not be configured to accept monetary credits via a credit or debit card. Some mobile gaming devices 256 may include a ticket reader and/or a ticket printer whereas some mobile gaming devices 256 may not, depending on the particular implementation.

In some implementations, the casino 251 may include one or more kiosks 260 that are configured to facilitate monetary transactions involving the mobile gaming devices 256, which may include cash out and/or cash in transactions. The kiosks 260 may be configured for wired and/or wireless communication with the mobile gaming devices 256. The kiosks 260 may be configured to accept monetary credits from casino patrons 262 and/or to dispense monetary credits to casino patrons 262 via cash, a credit or debit card, via a wireless interface (e.g., via a wireless payment app), via tickets, etc. According to some examples, the kiosks 260 may be configured to accept monetary credits from a casino patron and to provide a corresponding amount of monetary credits to a mobile gaming device 256 for wagering purposes, e.g., via a wireless link such as a near-field communications link. In some such examples, when a casino patron 262 is ready to cash out, the casino patron 262 may select a cash out option provided by a mobile gaming device 256, which may include a real button or a virtual button (e.g., a button provided via a graphical user interface) in some instances. In some such examples, the mobile gaming device 256 may send a “cash out” signal to a kiosk 260 via a wireless link in response to receiving a “cash out” indication from a casino patron. The kiosk 260 may provide monetary credits to the casino patron 262 corresponding to the “cash out” signal, which may be in the form of cash, a credit ticket, a credit transmitted to a financial account corresponding to the casino patron, etc.

In some implementations, a cash-in process and/or a cash-out process may be facilitated by the TITO system server 108. For example, the TITO system server 108 may control, or at least authorize, ticket-in and ticket-out transactions that involve a mobile gaming device 256 and/or a kiosk 260.

Some mobile gaming devices 256 may be configured for receiving and/or transmitting player loyalty information. For example, some mobile gaming devices 256 may be configured for wireless communication with the player tracking system server 110. Some mobile gaming devices 256 may be configured for receiving and/or transmitting player loyalty information via wireless communication with a patron's player loyalty card, a patron's smartphone, etc.

According to some implementations, a mobile gaming device 256 may be configured to provide safeguards that prevent the mobile gaming device 256 from being used by an unauthorized person. For example, some mobile gaming devices 256 may include one or more biometric sensors and may be configured to receive input via the biometric sensor(s) to verify the identity of an authorized patron. Some mobile gaming devices 256 may be configured to function only within a predetermined or configurable area, such as a casino gaming area.

FIG. 2C is a diagram that shows examples of components of a system for providing online gaming according to some aspects of the present disclosure. As with other figures presented in this disclosure, the numbers, types and arrangements of gaming devices shown in FIG. 2C are merely shown by way of example. In this example, various gaming devices, including but not limited to end user devices (EUDs) 264a, 264b and 264c are capable of communication via one or more networks 417. The networks 417 may, for example, include one or more cellular telephone networks, the Internet, etc. In this example, the EUDs 264a and 264b are mobile devices: according to this example the EUD 264a is a tablet device and the EUD 264b is a smart phone. In this implementation, the EUD 264c is a laptop computer that is located within a residence 266 at the time depicted in FIG. 2C. Accordingly, in this example the hardware of EUDs is not specifically configured for online gaming, although each EUD is configured with software for online gaming. For example, each EUD may be configured with a web browser. Other implementations may include other types of EUD, some of which may be specifically configured for online gaming.

In this example, a gaming data center 276 includes various devices that are configured to provide online wagering games via the networks 417. The gaming data center 276 may, for example, be a remote gaming server (RGS) or similar system in some implementations. The gaming data center 276 is capable of communication with the networks 417 via the gateway 272. In this example, switches 278 and routers 280 are configured to provide network connectivity for devices of the gaming data center 276, including storage devices 282a, servers 284a and one or more workstations 286b. The servers 284a may, for example, be configured to provide access to a library of games for online game play. In some examples, code for executing at least some of the games may initially be stored on one or more of the storage devices 282a. The code may be subsequently loaded onto a server 284a after selection by a player via an EUD and communication of that selection from the EUD via the networks 417. The server 284a onto which code for the selected game has been loaded may provide the game according to selections made by a player and indicated via the player's EUD. In other examples, code for executing at least some of the games may initially be stored on one or more of the servers 284a. Although only one gaming data center 276 is shown in FIG. 2C, some implementations may include multiple gaming data centers 276.

In this example, a financial institution data center 270 is also configured for communication via the networks 417. Here, the financial institution data center 270 includes servers 284b, storage devices 282b, and one or more workstations 286b. According to this example, the financial institution data center 270 is configured to maintain financial accounts, such as checking accounts, savings accounts, loan accounts, etc. In some implementations one or more of the authorized users 274a-274c may maintain at least one financial account with the financial institution that is serviced via the financial institution data center 270.

According to some implementations, the gaming data center 276 may be configured to provide online wagering games in which money may be won or lost. According to some such implementations, one or more of the servers 284a may be configured to monitor player credit balances, which may be expressed in game credits, in currency units, or in any other appropriate manner. In some implementations, the server(s) 284a may be configured to obtain financial credits from and/or provide financial credits to one or more financial institutions, according to a player's “cash in” selections, wagering game results and a player's “cash out” instructions. According to some such implementations, the server(s) 284a may be configured to electronically credit or debit the account of a player that is maintained by a financial institution, e.g., an account that is maintained via the financial institution data center 270. The server(s) 284a may, in some examples, be configured to maintain an audit record of such transactions.

In some alternative implementations, the gaming data center 276 may be configured to provide online wagering games for which credits may not be exchanged for cash or the equivalent. In some such examples, players may purchase game credits for online game play, but may not “cash out” for monetary credit after a gaming session. Moreover, although the financial institution data center 270 and the gaming data center 276 include their own servers and storage devices in this example, in some examples the financial institution data center 270 and/or the gaming data center 276 may use offsite “cloud-based” servers and/or storage devices. In some alternative examples, the financial institution data center 270 and/or the gaming data center 276 may rely entirely on cloud-based servers.

One or more types of devices in the gaming data center 276 (or elsewhere) may be capable of executing middleware, e.g., for data management and/or device communication. Authentication information, player tracking information, etc., including but not limited to information obtained by EUDs 264 and/or other information regarding authorized users of EUDs 264 (including but not limited to the authorized users 274a-274c), may be stored on storage devices 282 and/or servers 284. Other game-related information and/or software, such as information and/or software relating to leaderboards, players currently playing a game, game themes, game-related promotions, game competitions, etc., also may be stored on storage devices 282 and/or servers 284. In some implementations, some such game-related software may be available as “apps” and may be downloadable (e.g., from the gaming data center 276) by authorized users.

In some examples, authorized users and/or entities (such as representatives of gaming regulatory authorities) may obtain gaming-related information via the gaming data center 276. One or more other devices (such EUDs 264 or devices of the gaming data center 276) may act as intermediaries for such data feeds. Such devices may, for example, be capable of applying data filtering algorithms, executing data summary and/or analysis software, etc. In some implementations, data filtering, summary and/or analysis software may be available as “apps” and downloadable by authorized users.

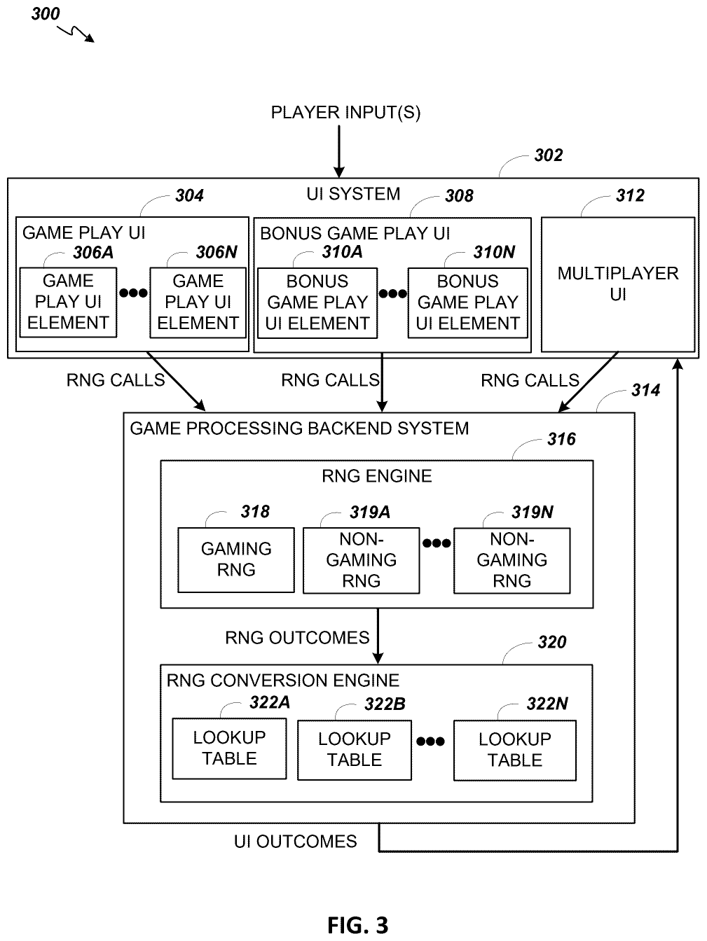

FIG. 3 illustrates, in block diagram form, an implementation of a game processing architecture 300 that implements a game processing pipeline for the play of a game in accordance with various implementations described herein. As shown in FIG. 3, the gaming processing pipeline starts with having a UI system 302 receive one or more player inputs for the game instance. Based on the player input(s), the UI system 302 generates and sends one or more RNG calls to a game processing backend system 314. Game processing backend system 314 then processes the RNG calls with RNG engine 316 to generate one or more RNG outcomes. The RNG outcomes are then sent to the RNG conversion engine 320 to generate one or more game outcomes for the UI system 302 to display to a player. The game processing architecture 300 can implement the game processing pipeline using a gaming device, such as gaming devices 104A-104X and 200 shown in FIGS. 1 and 2, respectively. Alternatively, portions of the gaming processing architecture 300 can implement the game processing pipeline using a gaming device and one or more remote gaming devices, such as central determination gaming system server 106 shown in FIG. 1.

The UI system 302 includes one or more UIs that a player can interact with. The UI system 302 could include one or more game play UIs 304, one or more bonus game play UIs 308, and one or more multiplayer UIs 312, where each UI type includes one or more mechanical UIs and/or graphical UIs (GUIs). In other words, game play UI 304, bonus game play UI 308, and the multiplayer UI 312 may utilize a variety of UI elements, such as mechanical UI elements (e.g., physical “spin” button or mechanical reels) and/or GUI elements (e.g., virtual reels shown on a video display or a virtual button deck) to receive player inputs and/or present game play to a player. Using FIG. 3 as an example, the different UI elements are shown as game play UI elements 306A-306N and bonus game play UI elements 310A-310N.

The game play UI 304 represents a UI that a player typically interfaces with for a base game. During a game instance of a base game, the game play UI elements 306A-306N (e.g., GUI elements depicting one or more virtual reels) are shown and/or made available to a user. In a subsequent game instance, the UI system 302 could transition out of the base game to one or more bonus games. The bonus game play UI 308 represents a UI that utilizes bonus game play UI elements 310A-310N for a player to interact with and/or view during a bonus game. In one or more implementations, at least some of the game play UI element 306A-306N are similar to the bonus game play UI elements 310A-310N. In other implementations, the game play UI element 306A-306N can differ from the bonus game play UI elements 310A-310N.

FIG. 3 also illustrates that UI system 302 could include a multiplayer UI 312 purposed for game play that differs or is separate from the typical base game. For example, multiplayer UI 312 could be set up to receive player inputs and/or presents game play information relating to a tournament mode. When a gaming device transitions from a primary game mode that presents the base game to a tournament mode, a single gaming device is linked and synchronized to other gaming devices to generate a tournament outcome. For example, multiple RNG engines 316 corresponding to each gaming device could be collectively linked to determine a tournament outcome. To enhance a player's gaming experience, tournament mode can modify and synchronize sound, music, reel spin speed, and/or other operations of the gaming devices according to the tournament game play. After tournament game play ends, operators can switch back the gaming device from tournament mode to a primary game mode to present the base game. Although FIG. 3 does not explicitly depict that multiplayer UI 312 includes UI elements, multiplayer UI 312 could also include one or more multiplayer UI elements.

Based on the player inputs, the UI system 302 could generate RNG calls to a game processing backend system 314. As an example, the UI system 302 could use one or more application programming interfaces (APIs) to generate the RNG calls. To process the RNG calls, the RNG engine 316 could utilize gaming RNG 318 and/or non-gaming RNGs 319A-319N. Gaming RNG 318 could corresponds to RNG 212 or hardware RNG 244 shown in FIG. 2A. As previously discussed with reference to FIG. 2A, gaming RNG 318 often performs specialized and non-generic operations that comply with regulatory and/or game requirements. For example, because of regulation requirements, gaming RNG 318 could correspond to RNG 212 by being a cryptographic RNG or pseudorandom number generator (PRNG) (e.g., Fortuna PRNG) that securely produces random numbers for one or more game features. To securely generate random numbers, gaming RNG 318 could collect random data from various sources of entropy, such as from an operating system (OS) and/or a hardware RNG (e.g., hardware RNG 244 shown in FIG. 2A). Alternatively, non-gaming RNGs 319A-319N may not be cryptographically secure and/or be computationally less expensive. Non-gaming RNGs 319A-319N can, thus, be used to generate outcomes for non-gaming purposes. As an example, non-gaming RNGs 319A-319N can generate random numbers for generating random messages that appear on the gaming device.

The RNG conversion engine 320 processes each RNG outcome from RNG engine 316 and converts the RNG outcome to a UI outcome that is feedback to the UI system 302. With reference to FIG. 2A, RNG conversion engine 320 corresponds to RNG conversion engine 210 used for game play. As previously described, RNG conversion engine 320 translates the RNG outcome from the RNG 212 to a game outcome presented to a player. RNG conversion engine 320 utilizes one or more lookup tables 322A-322N to regulate a prize payout amount for each RNG outcome and how often the gaming device pays out the derived prize payout amounts. In one example, the RNG conversion engine 320 could utilize one lookup table to map the RNG outcome to a game outcome displayed to a player and a second lookup table as a pay table for determining the prize payout amount for each game outcome. In this example, the mapping between the RNG outcome and the game outcome controls the frequency in hitting certain prize payout amounts. Different lookup tables could be utilized depending on the different game modes, for example, a base game versus a bonus game.

After generating the UI outcome, the game processing backend system 314 sends the UI outcome to the UI system 302. Examples of UI outcomes are symbols to display on a video reel or reel stops for a mechanical reel. In one example, if the UI outcome is for a base game, the UI system 302 updates one or more game play UI elements 306A-306N, such as symbols, for the game play UI 304. In another example, if the UI outcome is for a bonus game, the UI system could update one or more bonus game play UI elements 310A-310N (e.g., symbols) for the bonus game play UI 308. In response to updating the appropriate UI, the player may subsequently provide additional player inputs to initiate a subsequent game instance that progresses through the game processing pipeline.

Electronic gaming machines (EGMs) such as those discussed above may have cabinets with access panels, doors, slide-out trays, or separate enclosures (e.g., a bill validator cage) within the cabinet. Some such cabinets have a door to which one or more display devices and other components, such as button decks and bill validators, are mounted. Many EGMs use a door latch to connect a cabinet and a door such that the door can be closed and locked to the cabinet to prevent unwanted access, as well as opened to allow for maintenance and service of the EGM. However, the configuration of these latches and their actuation, locking, and unlocking can be challenging and difficult. For example, it may be desirable or required to have a latch at a location of the EGM where there is no access to the latch which may therefore require providing an actuation mechanism, such as a cable, within the EGM to another location where a person can access the actuation mechanism. This may also require providing a lock for the latch at the different location as well, such as a lock for a cover over the actuation mechanism. It can also be challenging to reduce the actions required by personnel to open and close the door using the latch, such as reducing the required turns of a key, manually resetting of the latch or lock, and positioning the latch to engage and retain the door in the closed position. For example, many latches require one or more components to be manually reset in order to function properly. It is desirable to reduce the actions taken by personnel to open and close the door in order to improve reliability and repeatability of the door latching properly and securely to the cabinet.

Provided herein are new and novel features for a door latch system that may be used for doors, such as doors for EGMs. Some embodiments provide a door latch with a housing, a cam (or pawl), and a trigger configured to retain the cam. The door latch is configured to engage with a stationary structure, which may be referred to as a striker (e.g., a striker bolt, molded striker, or wire form striker), in which the cam contacts and rotates about the striker to retain the striker within the door latch when the cam is retained by the trigger. While in a trigger closed position, the trigger retains the cam in its closed position and when the trigger is moved or pulled to a trigger open position, the cam is released and the cam can be disengaged from the striker, thereby unlocking and unlatching the door. In order to retain the cam in the closed position when the cam is engaged with the striker, the trigger is to be in a ready to latch position, which may be the trigger closed position.

The door latch systems provided herein are advantageously configured to automatically position the door latch so it is ready to latch with the striker. This configuration may include positioning the trigger in the ready to latch position, e.g., the trigger closed position. As described below, the door latch systems provided herein have an actuator configured to move the trigger into a position where it can retain the cam. The actuator may be positioned in a different location than the door latch and a cable may be connected to, and span between, the trigger and actuator. When the actuator is moved in one direction, the actuator moves the cable which in turn pulls the trigger from its trigger closed position to a trigger open position. With the trigger in the trigger open position, the cam can be released from its closed position and thereby release the striker. After this, if the trigger remains in the trigger open position, it is unable to engage with and retain the cam when the cam is reengaged with the striker, which is not desirable. The door latch systems herein advantageously have an elastic member, such as a spring, that exerts a force on the actuator and causes the actuator to move in the opposite direction back to its starting position. Moving the actuator moves the cable which pushes the trigger from the trigger open position to the trigger closed position. In the trigger closed position, the door latch is ready to latch with the striker because the trigger is configured to retain the cam when the cam is contacted and rotated by the striker. Many existing door latches cannot automatically return the trigger to such a ready to latch position. Further, some latches may have internal springs configured to rotate the cam, trigger, or both, but these springs are unable to move the trigger to the proper position when it is connected to a cable.

FIG. 4 depicts a side view of a door latch system according to disclosed embodiments. The door latch system 400 has a door latch 402 that has a housing 404, a cam 406 (which may also be considered a pawl), and a trigger 408. One side of the housing 404 is removed so internal aspects of the door latch 402 can be seen. The cam 406 is rotatably connected to the housing 404 such that the cam 406 can rotate about a first axis 410. The cam 406 also has a flag 414 that is configured to be detected by a sensor 416, which is described in more detail below. The trigger 408 is also rotatably connected to the housing 404 such that the trigger 408 can rotate about a second axis 412. The cam 406 is configured to rotate between a closed position and an open position, with FIG. 4 depicting the cam 406 in the closed position. In some embodiments, the cam 406 has a recess 418 and is configured to make contact with a striker (not shown) and to rotate about the first axis 410 to retain the striker within the recess 418 while in the closed position.

The trigger 408 is also configured to be in a first trigger position and a second trigger position, with FIG. 4 depicting the trigger 408 in the first trigger position. In some instances, the first trigger position may be considered a trigger closed position and the second trigger position may be considered a trigger open position. In the first trigger position, the trigger 408 is configured to retain the cam 406 in the closed position. As can be seen in FIG. 4, the trigger 408 has a retention surface 420 configured to prevent the cam 406 from rotating counterclockwise (in this example) and into the open position, thereby retaining the cam 406 in the closed position. The trigger 408 is also configured to release the cam 406 when the trigger 408 is moved or rotated to the second trigger position such that in the second trigger position, the trigger 408 does not retain the cam 406 in the closed position. This is discussed farther below.

The door latch system 400 also has an actuator 422 and a cable 424, with a first end 426 of the cable 424 connected to the trigger 408 and a second end 428 of the cable 424 connected to the actuator 422. The actuator 422 is configured to slide along a third axis 430 between a first actuator position and a second actuator position. FIG. 4 depicts the actuator 422 in the first actuator position. When moving from the first actuator position to the second actuator position, the actuator 422 is configured to move or pull the cable, such as in a direction away from the door latch 402 as illustrated with dashed arrows A1. When the cable 424 is moved, or pulled, away from the door latch 402, such as in the direction of dashed arrow A1 as caused by the actuator 422 moving from the first actuator position to the second actuator position, the cable also moves, or pulls, the trigger 408 and causes the trigger 408 to rotate about the second axis 412 (counterclockwise in this example) from the first trigger position to the second trigger position. These actuator 422 and cable 424 movements are thereby configured to cause the trigger 408 not to retain the cam 406 so that the cam 406 can rotate about the first axis 410 to the open position so the striker can be released from the cam 406. In some embodiments, the system 400 may have one or more cable retainers 423A and 423B configured to retain the cable in one or more fixed positions while allowing the cable to slide. These cable retainers may assist with configuring the system to be able to move the cable 424 and trigger 408 by moving the actuator 422.

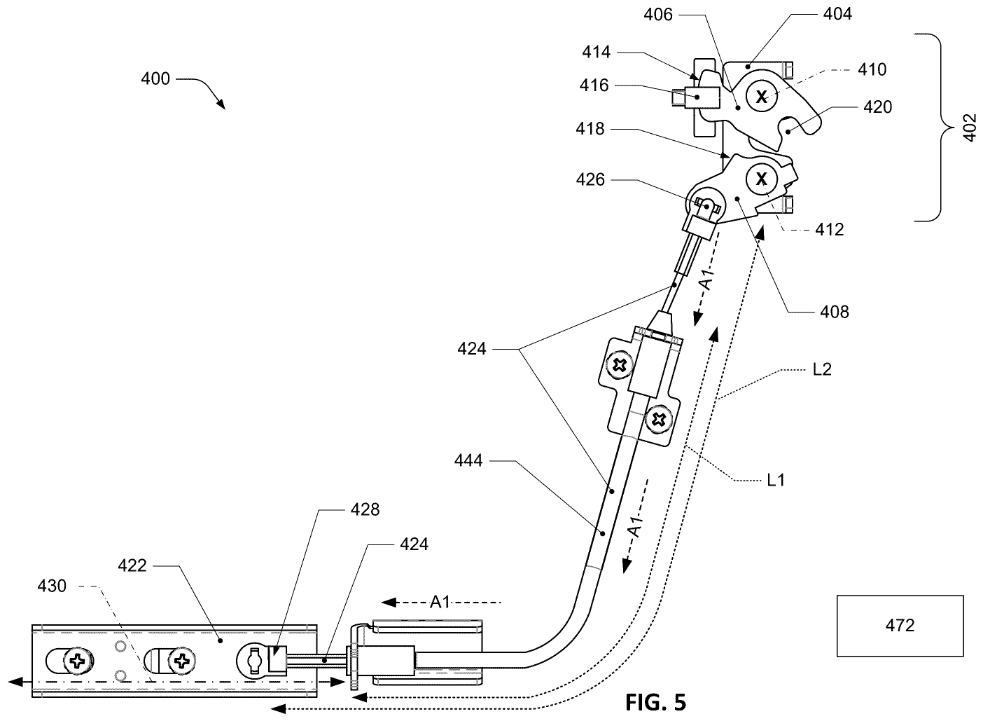

FIG. 5 depicts the side view of the door latch system of FIG. 4 in another configuration according to disclosed embodiments. Here, the actuator 422 has been moved to the second actuator position which in turn has caused the trigger 408 to be in the second trigger position, or trigger open position. As noted above, movement of the actuator 422 from the first actuator position (illustrated in FIG. 4) to the second actuator position (illustrated in FIG. 5) moves, or pulls, the cable 424 in one or more directions away from the door latch 402 which in turn moves, or pulls, the trigger 408. This movement by the cable 424 and actuator 422, causes the trigger 408 to rotate about the second axis 412 from the first trigger position to the second trigger position shown here in FIG. 5. With the trigger 408 in the second trigger position, the cam 406 is not retained by the trigger 408 and the cam 406 can rotate about the first axis 410 to the open position. The cam 406 in FIG. 5 is shown in the open position and in this position, the cam 406 can release the striker when opening the door and engage with and be rotated to the closed position when closing the door.

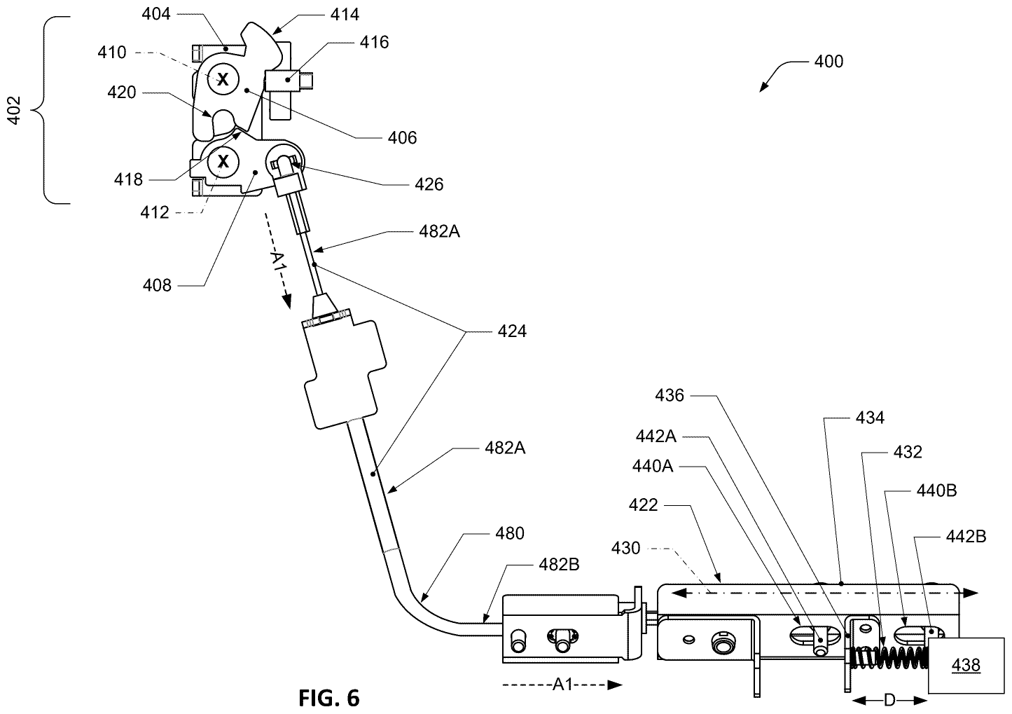

The door latch system 400 also has an elastic member that is configured to exert a force on the actuator 422 and cause the actuator 42 to move back to the first actuator position when the actuator 422 is moved out of the first actuator position. FIG. 6 depicts a back view of the door latch system of FIG. 4. Here, similar to FIG. 4, the other side of the housing 404 of the door latch 402 is removed so internal aspects of the door latch 402 can be seen. The cam 406 is in the closed position and the trigger 408 is in the first trigger position, or trigger closed position, such that the trigger 408 retains the cam 406 in the closed position. The back side of the actuator 422 is visible and an elastic member 432 of the system 400 is in contact with the actuator 422. This elastic member 432 is configured to exert a force against the actuator 422 to cause the actuator to slide back to the first actuator position. The elastic member 432 may be located in various positions to contact the actuator at a variety of locations. The elastic member may also be positioned between the actuator and a stationary component that is configured to remain stationary with respect to the actuator. This positioning allows the elastic member to exert the force on the actuator and cause the actuator to move relative to the stationary component. In some embodiments, the stationary component may be a surface of a door (when the door latch system 400 is a part of a door) or a cabinet (when the door latch system 400 is a part of a cabinet).

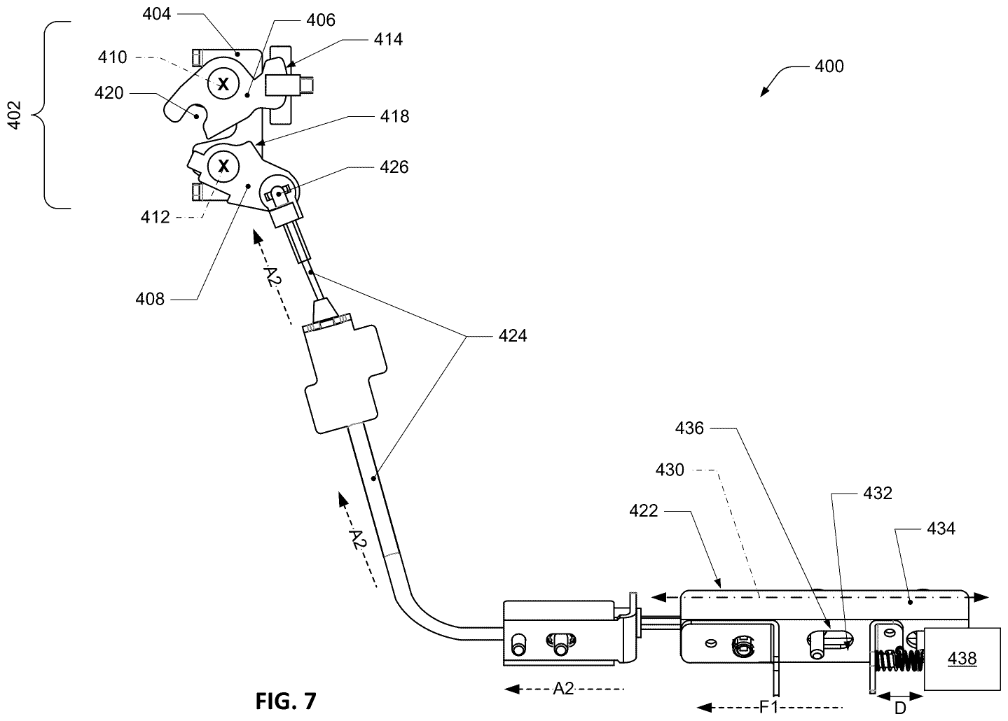

In some implementations, the actuator 422 has a body 434 and a first flange 436 that extends away from the body 434, as illustrated in FIG. 6. The elastic member 432 is in contact with the first flange 436 such that when the elastic member 432 exerts the force on the first flange 436, the actuator 422 is caused to move. Here, the elastic member 432 may be connected to, or in contact with a stationary component, represented by box 438 which may be a part of a door. This stationary component 438 is configured to remain stationary with respect to the actuator 422 such that the actuator 422 is configured to move relative to the stationary component 438. As the actuator 422 is moved from the first actuator position to the second actuator position, the elastic member 432 may be compressed between the first flange 436 and the stationary component 438. This movement of the actuator 422 from the first actuator position to the second actuator position reduces the distance D between the first flange 436 and the stationary component 438. For example, the distance D while the actuator 422 is in the first actuator position shown in FIG. 6 is greater than the distance D while the actuator 422 is in the second actuator position shown in FIG. 7. Compression of the elastic member 432 is configured to cause the elastic member 432 to exert a force opposite the compression, such as an extension force. This extension force by the compressed elastic member 432 causes the actuator 422 to move in the opposite direction and back to the first actuator position.

FIG. 7 depicts a back view of the door latch system of FIG. 5. Here, similar to FIG. 6, the other side of the housing 404 of the door latch 402 is removed so internal aspects of the door latch 402 can be seen. In FIG. 7, the actuator 422 is in the second actuator position such that it has slid, or translated, along the third axis 430 to the second actuator position. By moving to the second actuator position, the first flange 436 has also moved, the stationary component 438 has remained stationary, and the elastic member 432 has been compressed between the first flange 436 and the stationary component 438. Under compression, the elastic member 432 is configured to exert the force F1 in the direction as indicated by the dashed arrow. This force F1 is exerted against the first flange 436 of the actuator 422 and configured to cause the actuator 422 to move from the second actuator position (in FIGS. 5 and 7) back to the first actuator position (in FIGS. 4 and 6) in the direction of arrow A2. This movement by the actuator 422 moves, or pushes, the cable 424 in the opposite direction, e.g., opposite the direction of arrows A1, and towards the door latch 402 which in turn moves, or pushes, the trigger 408 to the first trigger position (of FIGS. 4 and 6). In this view of FIG. 7, the trigger 408 is configured to be rotated clockwise about the second axis 412 when moved, or pushed, by the cable 424 and actuator 422.

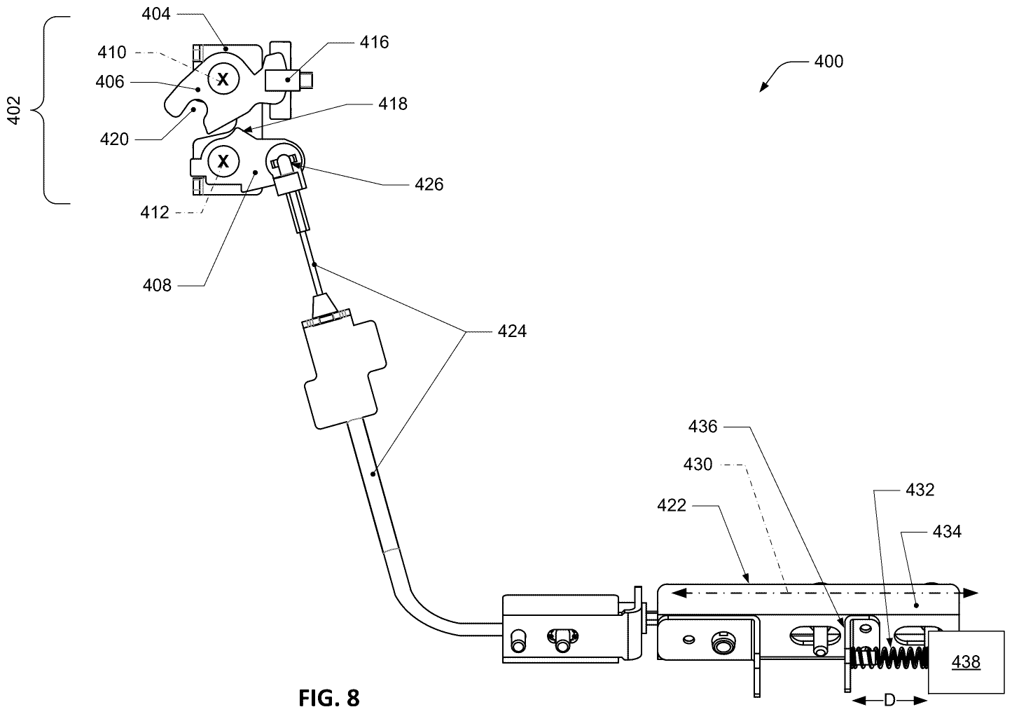

As noted herein, after the trigger 408 has been moved to the second trigger position such that the cam 406 is not retained by the trigger 408 and can rotate to the open position, the system 400 is configured to automatically position the trigger 408 back in the first trigger position so it is ready to retain the cam 406 when the cam 406 is rotated back to the closed position. Without repositioning the trigger 408 back to the first trigger position from the second trigger position, the trigger 408 is unable to retain the cam 406 and the door latch cannot function properly to retain a door in the closed position. The positioning of the trigger 408 and the cam 406 in a ready to latch state is illustrated in FIG. 8 which depicts the back view of the door latch system in another configuration according to disclosed embodiments.

Here in FIG. 8, the actuator 422 has been moved back to the second actuator position by the elastic member 432 which has moved, or pushed the cable 424, and in turn has moved, or pushed, the trigger 408 to the first trigger position. Referring back to FIG. 7, the force F1 and movement in directions of arrows A2 has caused the trigger 408 to rotate back to the first trigger position. The cable 424 movement may be considered to cause the trigger 408 to rotate (counterclockwise in FIGS. 7 and 8) about the second axis 412, which may be considered in a rotation direction opposite to the trigger's 408 rotation about the second axis 412 when moving from the first trigger position to the second trigger position. In FIG. 8, the cam 406 is also shown in the open position. This positioning of FIG. 8 may be considered a ready to latch position of the door latch system 400. In the ready to latch position, the trigger 408 is in the first trigger position and the cam 406 is not retained by the trigger 408, is not in the closed position, and may be in other positions besides the closed position. When in the ready to latch position, the cam 406 can be contacted by a striker and rotated about the first axis 410 to the closed position, and the trigger 408 is in the first trigger position and configured to retain the cam 406 as it rotates to the closed position.

In some implementations, like illustrated in FIGS. 4-8, the elastic member 432 is a compression spring. Under compression, the compression spring 432 is configured to exert the force, such as an extension force, in the opposite direction of the compression. As illustrated, when the compression spring 432 is compressed by movement of the actuator 422 from the first actuator position to the second actuator position, e.g., in a first direction indicated by arrows A1, the compression spring 432 is configured to exert the force F1 against the actuator 422 in the opposite direction of arrow A1 and move the actuator 422 in the direction of arrows A2 back to the first actuator position. In some implementations, the elastic member may be another type of component, such as a compressible polymer.

In some other embodiments, the elastic member may be configured to be extended, instead of compressed, by the movement of the actuator from the first actuator position to the second actuator position and configured to exert a compressive force to move the actuator back to the first actuator position. For example, the elastic member may be a tension spring that is stretched, or extended, when the actuator moves from the first actuator position to the second actuator position. While in this extended position, the tension spring is configured to exert a compressive force that can move the actuator back to the first actuator position. Similar to the elastic member 432, the extension spring may also be connected to the actuator and a stationary component such that movement of the actuator extends the extension spring between the actuator and stationary component.

In some embodiments, the actuator 422 may have one or more slots and one or more connectors that together are configured to provide a sliding motion for the actuator 422. Referring back to FIG. 4, the body 434 of the actuator 422 has a first slot 440A, a first connector 442A extending through the first slot 440A, a second slot 440B, and a second connector 442B extending through the second slot 440B. The first and second connectors 442A and 442B may be connected to the same, or another, stationary component, such as a door or cabinet, and remain stationary with respect to the movement of the actuator 422. As illustrated in FIGS. 4-8, the first and second slots 440A and 440B of the actuator 422 are configured to move, or slide, about the first and second connectors 442A and 442B. The first and second connectors 442A and 442B are therefore configured to move within the first and second slots 440A and 440B, respectively, as the actuator 422 is moved along the third axis 430. In some implementations, the first and second connectors 442A and 442B may be cylinders, have a cylindrical shape, or be screws, bolts, pins, or the like.

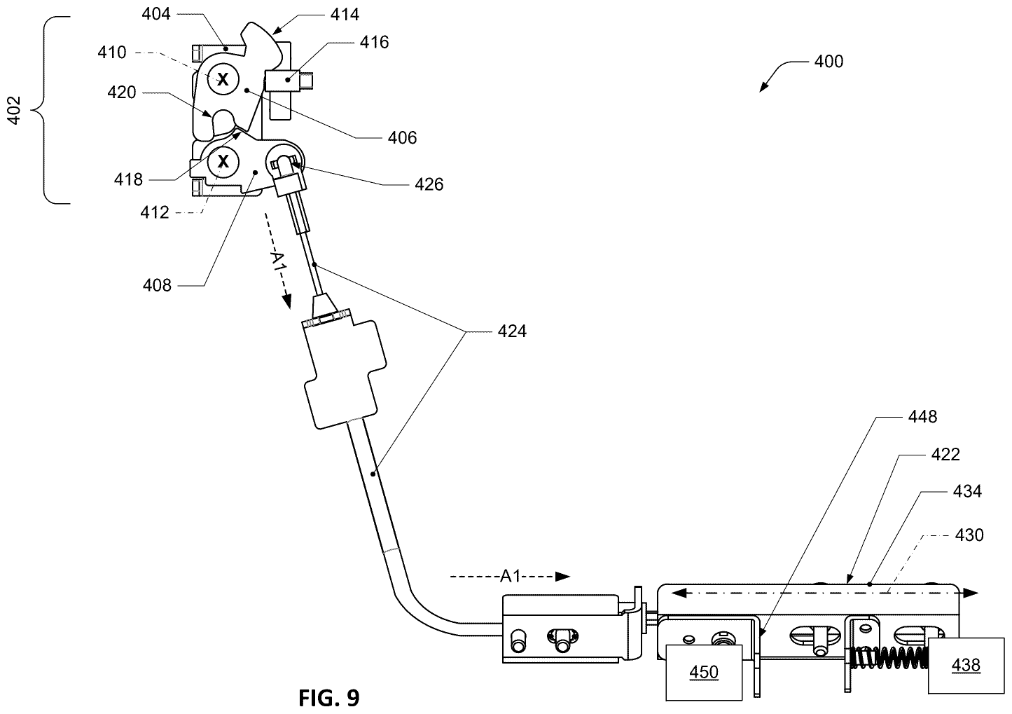

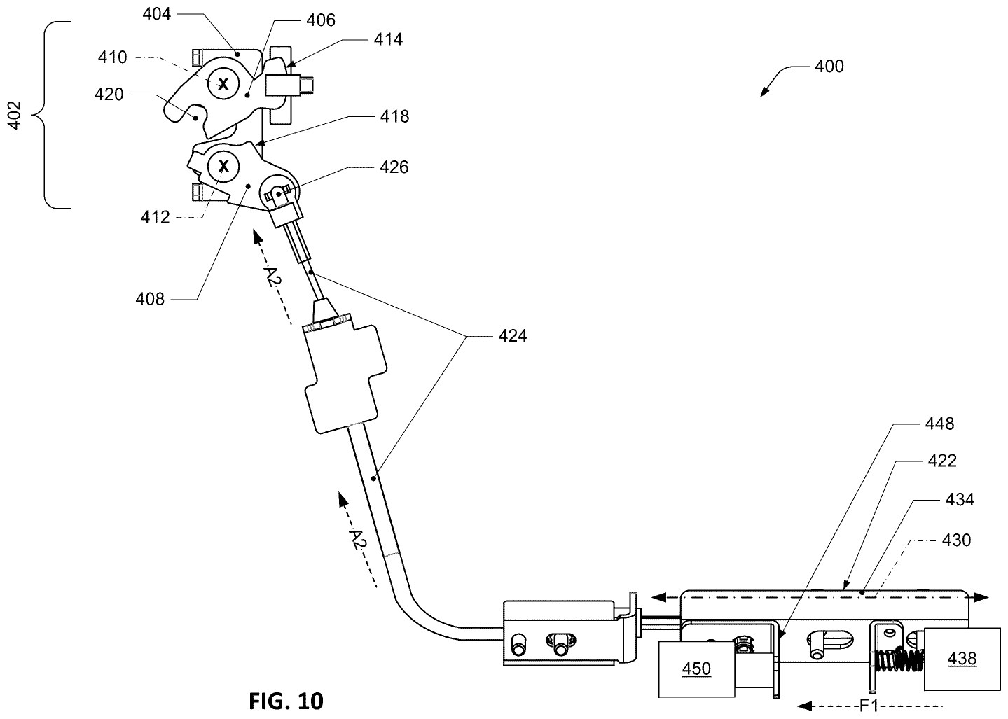

Moving the actuator from the first actuator position to the second actuator position to open the door latch may be performed in various manners. As mentioned herein, the door latch system 400 is configured to open the door latch 402 when the actuator 422 is moved from the first actuator position to the second actuator position. This actuator 422 movement pulls the cable away from the door latch 402 and pulls the trigger 408 to the second trigger position so that the cam 406 is able to rotate about the first axis 410 and release the striker. In some embodiments, a lock mechanism is configured to contact and move the actuator from the first actuator position to the second actuator position. FIG. 9 depicts the back view of the door latch system of FIG. 6 with a lock mechanism. Here, the system 400 has a lock mechanism 450, represented by a box, that is the movement mechanism configured to contact and move the actuator 422 from the first actuator position to the second actuator position. The lock mechanism 450 may be positioned in various locations proximate to the actuator 422 and configured to contact various aspects of the actuator 422. In the examples of FIGS. 4-10, the lock mechanism 450 is configured to contact a second flange 448 of the actuator 4. The second flange 448 extends away from the body 434 of the actuator 422 and is configured to be contacted and moved by the lock mechanism 450 to move the actuator 422 in the direction of arrow A1 from the first actuator position to the second actuator position. FIG. 10 depicts the door latch system of FIG. 9 in another configuration. Here, the system is the same as FIG. 7, except for noted differences. In this example, an element of the lock mechanism 450 has contacted the second flange 448 and moved in the direction of arrow A1 which has moved the second flange 448 and the actuator 422 to the second actuator position.

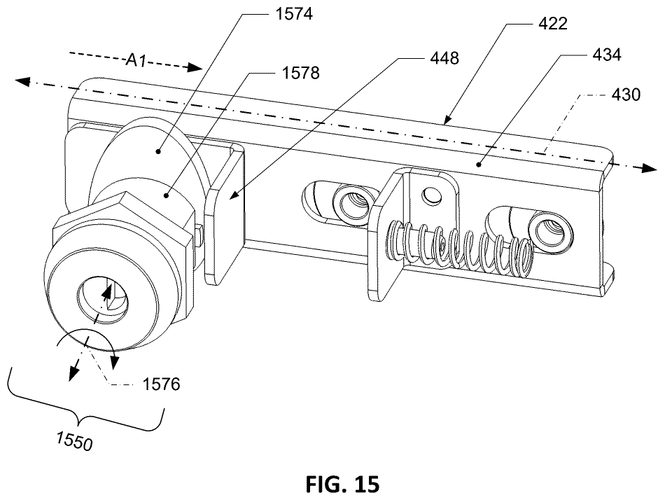

The lock mechanism 450 may have different configurations and such configurations are able to contact and move the second flange 448. In some embodiments, the lock mechanism may have a secure key lock with a hybrid circular/elliptical cam mounted at one end. FIG. 15 depicts an off-angle view of the actuator and an example lock mechanism. Here, the lock mechanism 1550 has a cam 1574 with an elliptical and circular shape and that is configured to be rotated about an axis 1576 as the key is rotated in the clockwise direction (of this illustration). This rotation of the cam 1574 causes the cam 1574 to contact the second flange 448 and move the actuator in the first direction A1. The cam 1574 may have a central aperture that may closely match the shape of the lock's spindle 1578 or may have a generic square aperture working with an adaptor.

In some implementations, the lock mechanism 450 (and lock mechanism 1550) may be configured to return to its original position after contacting and moving the second flange. By returning to its original position, the lock mechanism 450 does not prevent the movement of the actuator 422 back from the second actuator position to the first actuator position by the elastic member 432. In some other implementations, the lock mechanism 450 may be configured to be returned to its initial position by the movement of the actuator 422 back to the first actuator position. As illustrated in FIG. 10, the elastic member 432 exerts the force F1 in the direction of the F1 arrow. This force F1 and movement may be configured to move the lock mechanism 450 back to its original position. By configuring the lock mechanism 450 to move back to its original position, or to be movable by the actuator 42, the lock mechanism 450 is configured to not impede the movement of the actuator 422 from the second actuator position to the first actuator position (or ready to latch position) by the elastic member 432.

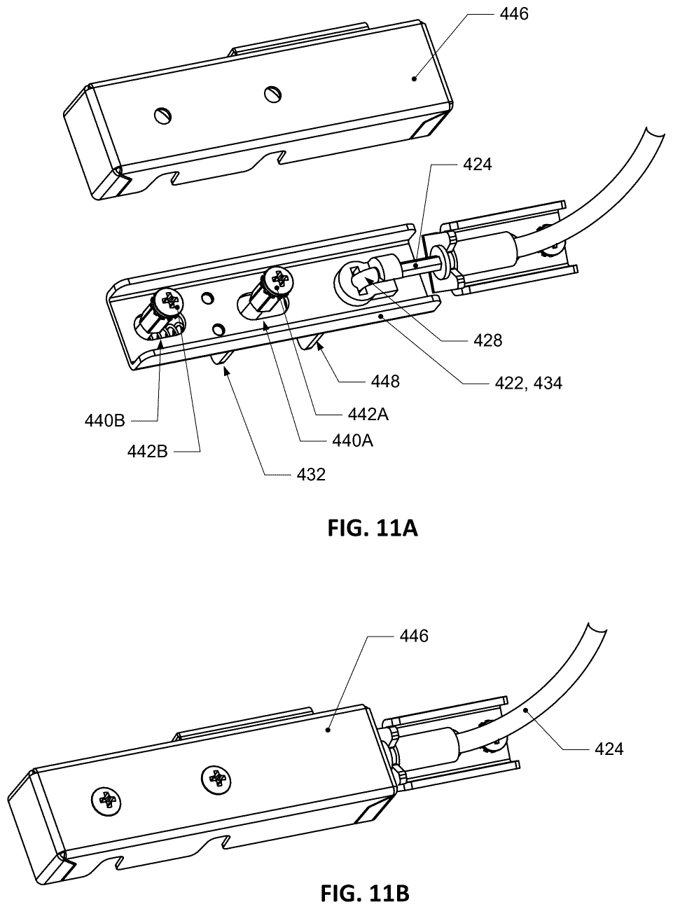

The door latch system 400 may have one or more covers to help the functionality of its elements and protect its elements from damage or obstruction. FIG. 11A depicts an off-angle view of a portion of the door latch system of FIG. 4 and FIG. 11B depicts an exploded view of the portion of the door latch system of FIG. 11A. Here, the door latch system has a cover 446 configured to be positioned around a portion of the actuator 422. FIG. 11B illustrates the cover 446 positioned over the actuator 422. As can be seen, the cover 446 extends around portions of all sides except the back of the actuator 422 to prevent the obstruction of movement of the first flange 436 and second flange 448.

In some implementations, the system 400 may have a cover, or a sheath 444, around a portion of the cable 424. Referring back to FIG. 5, the sheath 444 is identified and may extend around the entire circumference of the cable and along a length L1 of the cable 424 that is less than the length L2 of the cable 424 itself. The sheath 44 may have various advantages, such as guiding and holding the cable in place, allowing the cable to move or slide back and forth, and protecting the cable from obstruction or impingement by other elements in the EGM in which it is placed. While the sheath 442 has numerous advantages, it may cause unwanted resistance against the cable 424 movement, in some instances, which can prevent trigger 408 from being returned to the ready to latch position, or first trigger position. For instance, some door latches have axial springs within the trigger, but these springs are unable to rotate the trigger enough, or at all, when the trigger is connected with a cable 424 or a cable 424 with a sheath 444 as described.

As provided herein, the system 400 is configured to overcome resistance exerted on the cable 424, whether alone or with the sheath 444, and move the trigger 408 back to the first trigger position or ready to latch position (e.g., in FIG. 8). The elastic member 432 is configured to exert enough force F1 against the actuator 422 and cable 424 connected thereto to move the actuator 422 to the first actuator position (illustrated in FIGS. 4, 6, and 8) and thereby move the cable towards the door latch 402 and move the trigger 408 to the first trigger position, or ready to latch position, illustrated in FIG. 8.

In some embodiments, the cable 424 may have one or more bends and one or more straight sections. The geometry and positioning of the cable 424 may affect the resistance exerted on the cable 424 during its movement. For example, in FIG. 6, the cable has one bend 480 and two straight sections 482A and 482B on either side of the bend 480. The cable 424 of system 400 provided herein is configured to be moved by the actuator 422, including when the cable 424 has one or more bends, like bend 480, and one or more straight sections, like sections 482A and 482B.

In some embodiments, the system 400 has the sensor 416 configured to detect the presence or absence of the flag 414 of the cam 406. Referring back to FIG. 4, the sensor 416 is positioned near, or proximate to, the flag 414 and cam 406. The sensor 416 may be, in some instances, an optical sensor that has an emitter and a receiver and that is configured to detect when an object, such as the flag 414, breaks the line of sight between the emitter and the receiver. For example, in FIG. 4 the flag is in a first flag position such that it is outside the sensor 416. In the instances that the sensor 416 is an optical sensor, the sensor's line of sight is not broken by the flag 414 in this first flag position. When in this configuration, this may indicate that the door latch 402 is in the closed position. In FIG. 5, the cam 406 is in the open position and the flag 414 is in a second flag position such that it is positioned inside the sensor 416. In the instances that the sensor 416 is an optical sensor, this positioning of the flag in the second flag position may break the line of sight between the sensor's 416 emitter and receiver and thereby indicate that the door latch 402 is open.

The sensor 416 may be configured to generate one or more signals and be electrically connected to a controller with one or more memories and one or more processors, and the one or more memories may store instructions to cause the one or more processors to receive the signals from the sensor 416 and make determinations based on these signals. With respect to FIG. 4, the controller 472 is configured to determine from the signals of the sensor 416 that the door latch 402 is in the closed position. With respect to FIG. 5, the controller is configured to determine from the signals of the sensor 416 that the door latch 402 is in the open position. In some embodiments, the instructions of the controller may be further configured to cause a notification to issue indicating that the door latch is open.

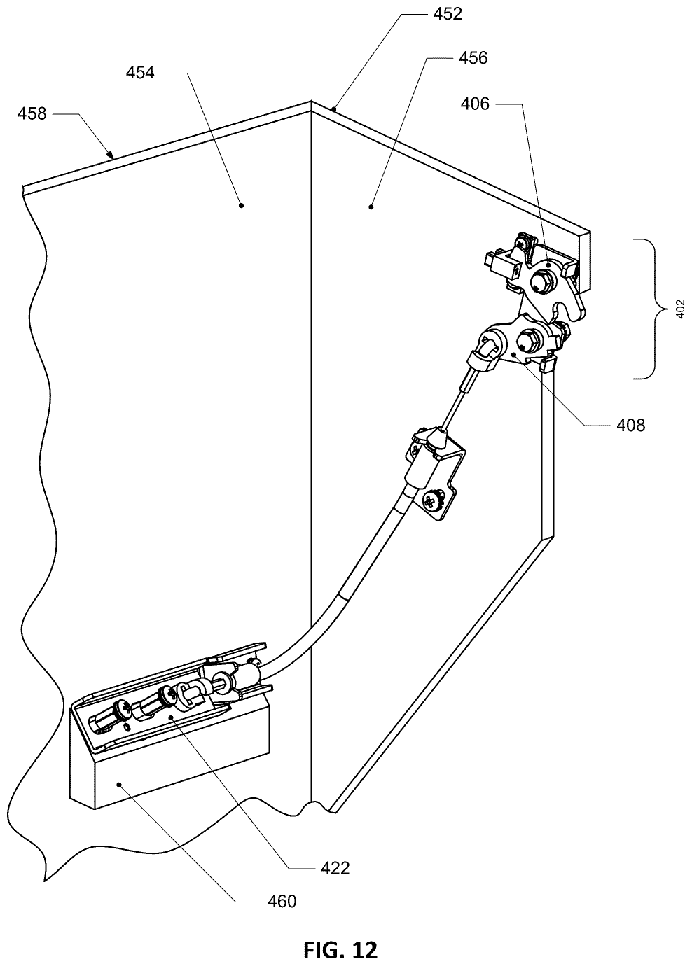

In some embodiments, the door latch system 400 provided herein may be attached to, or a part of, a door. FIG. 12 depicts an off-angle view of the door latch system of FIG. 4 along with a portion of a door. The portion of the door 452 has first inside section 454 and a second inside section 456 next to, and oriented at a different angle with respect to, the first inside section 454, such as perpendicular. In some instances, the second inside section 456 may be a side of the door 452. The door 452 also includes a first outside section 458 opposite the first inside section 454. The housing 404 of the door latch 402 is connected to the second inside section 456 and the actuator 422 is slidably connected to a stationary structure 460 of the first inside section 454. As can be seen, the actuator 422 is positioned at a different location within the door 452 with respect to the door latch 402. The door latch system 400 advantageously allows the door latch 402 to be placed in this location and the actuator to be placed at a different location where it can be more easily accessed by personnel. The door 452 and door latch system 400 may have the lock mechanism (not visible) that may be accessible through the first outside section 458. For example, the lock mechanism may be configured to receive a key on, by, or through the first outside section 458, to contact the actuator 422, such as on the second flange like discussed above, and to rotate about an axis and thereby cause the actuator 422 to move from the first actuator position to the second actuator position as provided herein.

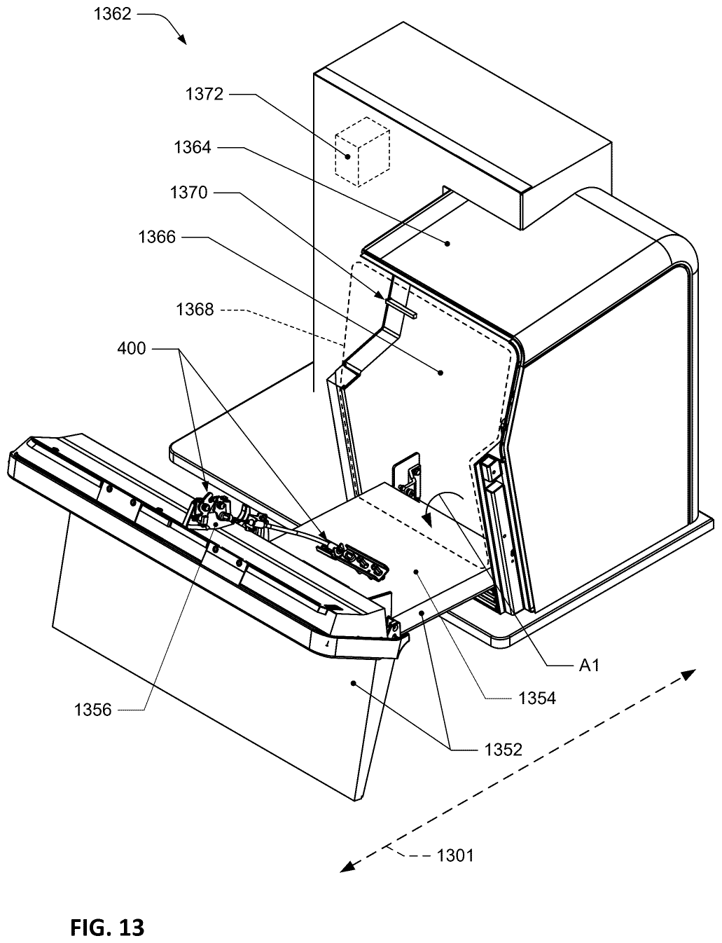

In some embodiments, the door latch system 400 is attached to a door of an EGM. The cabinet of the EGM may have the striker and the door latch of the door latch system may be configured to engage with the striker on the door to retain the door in a closed position. For example, the door 452 may be a door of an EGM. FIG. 13 depicts an isometric view of an electronic gaming machine according to disclosed embodiments. The electronic gaming machine (EGM) 1362 has a cabinet 1364 defining an internal compartment 1366 which may be considered an area inside of the cabinet 1364. The cabinet 1364 also has the door 1352 rotatably connected to the cabinet 1364. The door 1352 is configured to rotate about a hinge axis that is located towards a bottom portion of the door 1352 which may also be located towards the bottom of the cabinet 1364. In some implementations, like here, the door 1352 is configured to open outwards and downwards towards the floor 1301 as indicated by the arrow A1. The floor may be considered an omnibus term for the floor, ground, or other support structure on which the EGM is directly or indirectly positioned. For example, many EGMs are positioned on the floor, or on a support structure on the floor, of a casino or other location.

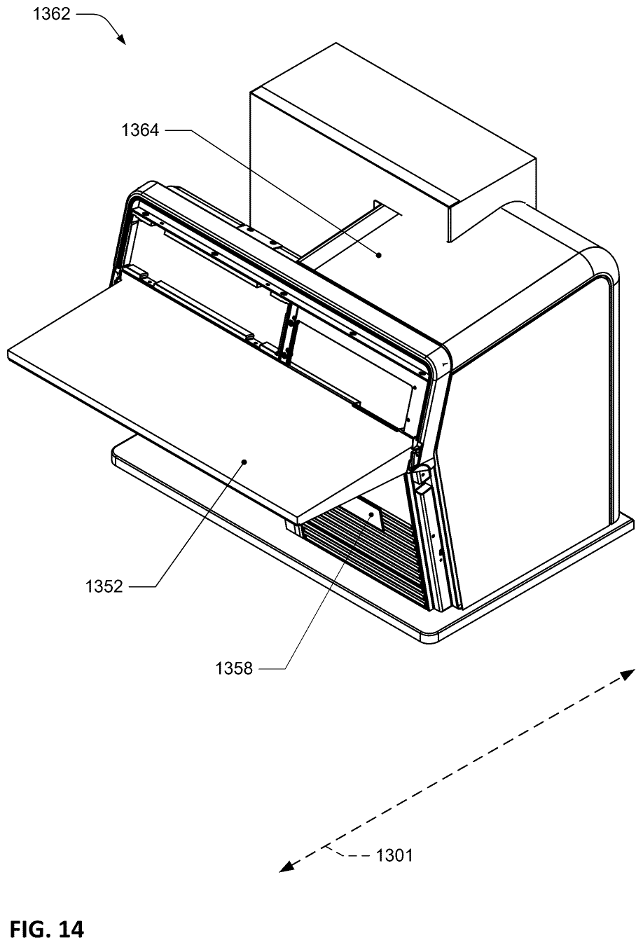

The cabinet 1364 also has an opening 1368 through which access can be made into the internal compartment 1366 for various reasons. This may include maintenance, service, removing components like a cashbox or electronics, etc. During normal operations of EGM 1362, the opening 1368 is covered by the door 1352 and access is prevented to the internal compartment 1366. To provide and restrict access to the internal compartment 1366, the door 1352 is configured to rotate about the hinge axis between a closed position and one or more open positions. FIG. 13 depicts the door 1352 in the open position and FIG. 14 depicts the electronic gaming machine of FIG. 13 with the door in a closed position according to various embodiments. As illustrated in these Figures, when the door 1352 is in the open position, the opening 1368 is uncovered and access to the internal compartment 1366 is provided through the opening 1368; while in the closed position, the door 1352 covers the opening 1368 of the cabinet 1364 and the internal compartment 1366 is not accessible through the opening 1368.

In FIG. 13, the EGM 1362 has the door latch system 400 provided herein which is connected to the door 1352. This door latch system 400 of the EGM 1362 has the various features and functions as described herein. The cabinet 1364 has a door latch interface 1370 configured to be engaged by the door latch of the door latch system 400. In some embodiments, the door latch interface 1370 may be a striker. Because some features of the door latch system 400 may not be clearly visible in FIG. 13, the functionality of the EGM 1362 will be described using FIG. 13 as well as FIGS. 4-12 with reference to the door latch system 400. For example, the door 1352 in FIG. 13 has the first inside section 1354 and the second inside section 1356 to which the door latch 402 is connected. The door 1352 also has the first outside section 1358 as illustrated in FIG. 14. It is through this outside section 1358 that a key may be inserted into the lock mechanism to move the actuator from the first actuator position to the second actuator position, as described herein. As described above with respect to FIG. 10, in some embodiments the actuator 422 is configured to rotate or move the lock mechanism 450 in an opposite direction of the lock mechanism's 450 initial movement. This may include causing the lock mechanism to rotate, move linearly, or both.

When the door 1352 is in the open position like shown in FIG. 13, the door latch system 400 is configured to position the door latch in the ready to latch position illustrated in FIG. 8. This includes the actuator 422 causing the trigger 408 to be in the first trigger position and the cam 406 to be in the open position, as shown in FIG. 8. When the door 1352 is moved to the closed position, the cam 406 in the open position (like in FIG. 8) is configured to engage with the striker 1370. This engagement may include the cam 406 and the striker 1370 becoming in contact with each other and the striker 1370 moving into the recess 420 of the cam 406 (as identified in FIGS. 4 and 8). As the cam rotates about the first axis 410, the cam 406 is retained by the retention surface 420 of the trigger 408 such that the cam 406 is in the closed position illustrated in FIGS. 4 and 6. In this closed position, the cam 406 retains the striker 1370 within the recess 420 and the trigger 408 retains the cam 406 in the closed position, thereby latching the door 1352 to the cabinet 1364 in the closed position.

In some embodiments, to open the door 1352 from the closed position, the lock mechanism 450 may be actuated by turning a key which in turn causes the actuator 422 to move from the first actuator position to the second actuator position, as illustrated in FIGS. 9 and 10. This movement of the actuator 422 moves, or pulls, the cable 424 away from the door latch 402 which in turn moves, or pulls, the trigger 408 to the second trigger position. With the trigger 408 in the second trigger position, the cam 406 is not retained by the trigger 408 and the cam 406 can rotate about the first axis 410 and release, or disengage, the striker 470 from the recess 420. As also provided above, following this movement, the door latch system 400 is configured to return the trigger 408 to the first trigger position so it is in the ready to latch position as illustrated in FIG. 8. Once the trigger 408 is moved to the second trigger position and the cam 406 releases the striker 1370, the door latch is automatically repositioned to the ready to latch position of FIG. 8. This can advantageously place the door 1352 in a ready to close position without any intervention by a person, such as turning a key or manually moving any element of the door latch system.

In some embodiments, the door latch system 400 of the EGM 1362 has the optical sensor 416 described above. The EGM may have a controller 1372 with one or more processor and one or more memories that store instructions for controlling the one or more processors. The instructions may be configured to cause the processor to receive signals from the optical sensor 416 and make one or more determinations based the signals. For example, the controller 1372 of the EGM may be configured to determine that the door latch 402 is open or closed based on determining whether the flag 414 of the cam 406 is in the first flag position, e.g., FIG. 4, and outside the optical sensor or in the second flag position, e.g., FIG. 5, and inside the optical sensor such that the line of sight between the emitter and receiver is broken; this may be considered detecting the presence of the flag 414.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

While the disclosure has been described with respect to the figures, it will be appreciated that many modifications and changes may be made by those skilled in the art without departing from the spirit of the disclosure. Any variation and derivation from the above description and figures are included in the scope of the present disclosure as defined by the claims.

What is claimed is:

1. A door latch system, comprising:
a door latch having:
a housing,
a cam having a flag, positioned inside the housing, rotatably connected to the housing, and configured to be in a closed position and an open position, and
a trigger positioned inside the housing, rotatably connected to the housing, and configured to be in a first trigger position and a second trigger position;
an actuator separate from the housing and configured to slide along an axis between a first actuator position and a second actuator position;
a cable having a first end connected to the trigger and a second end connected to the actuator; and
an elastic member contacting the actuator, wherein:
in the first trigger position, the trigger is configured to retain the cam in the closed position,
the trigger is configured to release the cam from the closed position when moving from the first trigger position to the second trigger position,
in the second trigger position, the trigger does not retain the cam in the closed position,
the actuator is configured to pull the cable when moving from the first actuator position to the second actuator position and thereby cause the cable to move the trigger from the first trigger position to the second trigger position,
the elastic member is configured to exert a force on the actuator and move the actuator from the second actuator position to the first actuator position, and
the actuator is configured to push the cable when moving from the second actuator position to the first actuator position and thereby cause the cable to move the trigger from the second trigger position to the first trigger position.

2. The door latch system of claim 1, wherein:
the actuator has a body and a first flange extending away from the body, and
the elastic member is:
in contact with the first flange, and
configured to move the first flange and thereby move the actuator from the second actuator position to the first actuator position.

3. The door latch system of claim 2, wherein:
the actuator further comprises a second flange extending away from the body, and
the second flange is configured to be contacted and moved by a lock mechanism and thereby move the actuator from the first actuator position to the second actuator position.

4. The door latch system of claim 3, further comprising the lock mechanism.

5. The door latch system of claim 1, wherein the actuator has:
a body having one or more slots, and
one or more cylinders that each extend through a respective slot.

6. The door latch system of claim 1, further comprising an optical sensor configured to detect the presence of the flag.

7. The door latch system of claim 6, wherein:
in the closed position, the flag is in a first flag position,
in the open position, the flag is in a second flag position, and
the optical sensor is configured to generate one or more signals based on whether the flag is in the first flag position or the second flag position.

8. The door latch system of claim 1, wherein the elastic member is a compression spring configured to be compressed in the second actuator position.

9. The door latch system of claim 1, wherein the elastic member is a tension spring configured to be extended in the second actuator position.

10. The door latch system of claim 1, further comprising a cover over at least a portion of the actuator.

11. The door latch system of claim 1, further comprising a sheath around a length of the cable.

12. An electronic gaming machine, comprising:
a cabinet defining an internal compartment and an opening that provides access to the internal compartment, and having a latch interface;
a door rotatably connected to the cabinet and configured to rotate between a closed door position in which the door covers the opening and one or more open door positions in which the door is away from the opening; and
a door latch system having:
a door latch positioned in a first location on a first side of the door and having:
a housing,
a cam having a flag, positioned inside the housing, rotatably connected to the housing, and configured to be in a closed position and an open position, and
a trigger positioned inside the housing, rotatably connected to the housing, and configured to be in a first trigger position and a second trigger position,
an actuator positioned in a second location on the first side of the door and slidably connected to the door such that the actuator is configured to slide along an axis between a first actuator position and a second actuator position,
a cable having a first end connected to the trigger and a second end connected to the actuator, and
an elastic member contacting the actuator and the door,
wherein:
the door latch is configured to engage with the latch interface,
in the first trigger position, the trigger is configured to retain the cam in the closed position,
in the second trigger position, the trigger does not retain the cam in the closed position,
the actuator is configured to pull the cable when moving from the first actuator position to the second actuator position and thereby cause the cable to move the trigger from the first trigger position to the second trigger position,
the elastic member is configured to exert a force on the actuator and move the actuator from the second actuator position to the first actuator position, and
the actuator is configured to push the cable when moving from the second actuator position to the first actuator position and thereby cause the cable to move the trigger from the second trigger position to the first trigger position.

13. The electronic gaming machine of claim 12, wherein:
the actuator has a body and a first flange extending away from the body,
the door has a stationary component adjacent to the first flange, and
the elastic member:
is in contact with and spans between the first flange and the stationary component, and
is configured to move the first flange and thereby move the actuator from the second actuator position to the first actuator position.

14. The electronic gaming machine of claim 12, further comprising a rotating lock mechanism configured to:
receive a key on a second side of the door,
contact the actuator, and
be rotated in a first direction about a rotation axis and thereby move the actuator from the first actuator position to the second actuator position.

15. The electronic gaming machine of claim 14, wherein the actuator is further configured to contact and rotate the rotating lock mechanism in a second direction opposite the first direction when moved by the elastic member from the second actuator position to the first actuator position.

16. The electronic gaming machine of claim 12, wherein:
the actuator has a body having one or more slots,
the door latch system further has one or more connectors, and
each connector extends through a respective slot and is connected to the door.

17. The electronic gaming machine of claim 12, wherein:
the door latch system further has a sheath around a length of the cable and attached to the door, and
the cable has at least one bend and/or one straight section.

18. The electronic gaming machine of claim 12, further comprising an optical sensor configured to detect the presence of the flag.

19. The electronic gaming machine of claim 18, further comprising a controller configured to receive one or more signals generated by the optical sensor, wherein:
in the closed position, the flag is in a first flag position,
in the open position, the flag is in a second flag position, and
the optical sensor is configured to generate the one or more signals based on whether the flag is in the first flag position or the second flag position.

20. The electronic gaming machine of claim 12, wherein:
movement of the actuator from the first actuator position to the second actuator position is configured to allow the door to be opened by causing the cable to move the trigger to the second trigger position to thereby not retain the cam such that the cam is configured to disengage from the latch interface,
the cam is configured to engage with the latch interface and be rotated about a rotation axis of the cam when the door is moved to the closed position, and
movement of the actuator from the second actuator position to the first actuator position is configured to allow the door to be retained in the closed position by causing the cable to move the trigger to the first trigger position such that the trigger is configured to retain the cam when the cam is engaged and rotated by the latch interface.
